(19) United States
(12) Patent Application Publication
(10) Pub. No.: US 2011/0129781 A1
(43) Pub. Date: Jun. 2, 2011

(54) Methods of forming a pattern using photoresist compositions

(76) Inventors: Kyoung-Mi Kim, Anyang-si (KR); Young-Ho Kim, Yongin-si (KR)

(21) Appl. No.: 12/952,513

(22) Filed: Nov. 23, 2010

(30) Foreign Application Priority Data
Nov. 27, 2009 (KR) 10-2009-0116217

(51) Int. Cl. G03F 7/20

(52) U.S. Cl. 430/323; 430/325

(57) ABSTRACT

In a photoresist composition, methods of forming a pattern using the same, and methods of manufacturing a semiconductor device using the same A photoresist film may be formed on a substrate by coating a photoresist composition including a polymer and a solvent. The polymer includes a first repeating unit and a second repeating unit. The first repeating unit has a diazoketo group and a second repeating unit has a group containing silicon. A photoresist pattern is formed by partially exposing the photoresist film and developing the photoresist film. A pattern having an improved etching resistance and uniformity of critical dimension is formed.

### CLAIM OF PRIORITY

This application claims priority under 35 USC §119 to Korean Patent Application No. 10-2009-0116217, filed on Nov. 27, 2009 in the Korean Intellectual Property Office (KIPO), the contents of which are herein incorporated by reference in its entirety.

### BACKGROUND

Example embodiments relate to photoresist compositions, methods of forming a pattern using the same, and methods of manufacturing a semiconductor device using the same.

Organic photosensitive materials such as photoresist compositions may be changed physically or chemically by light and/or radiation energy. The organic photosensitive materials may be applied to microfabrication technologies such as a photolithography process, and have been used for manufacturing electronics, e.g., integrated circuit (IC) devices, memory devices, printed circuit boards (PCBs), microelectromechanical systems (MEMS), display devices, image display devices, etc. For example, in a microfabrication process of a semiconductor device, a chemically amplified photoresist suitable for a lithography process using a light source such as a far ultraviolet ray, e.g., KrF excimer laser (248 nm), ArF excimer laser (193 nm), F₂ excimer laser (157 nm) or extreme ultraviolet (EUV, 13 nm) has been used in order to get high sensitivity.

Generally, a chemically amplified photoresist may be formed by mixing a photoacid generator and an acid-reactive polymer. In a chemical amplification, active species generated by one photon may cause a chain reaction so that quantum yield may greatly increase. In the chemically amplified photoresist, an acid may be generated from the photoacid generator when exposed to light, and combination or decomposition of the acid-reactive polymer may occur by chemical action, i.e., catalyzation of the acid. In a process of PEB (post-exposure bake), the acid in an exposed portion may serve as a catalyst for the acid-reactive polymer, thereby amplifying the chemical reaction and causing a difference of solubility between the exposed portion and a non-exposed portion. However, the acid generated in the exposed portion may diffuse to the non-exposed portion in the PEB process, so that a line width roughness of a pattern may be increased and a gap between the patterns may become wider. Additionally, the acid on a surface thereof may be neutralized by an alkali chemical species, e.g., ammonia (NH₃) in the atmosphere. As a result, reactivity of the acid may be decreased, and a hard-soluble layer may be formed on the surface, thereby causing a nonuniform pattern profile.

### SUMMARY

Example embodiments provide non-chemically amplified photoresist compositions having an improved pattern profile and etching resistance.

Example embodiments provide methods of forming a pattern using the non-chemically amplified photoresist compositions.

Example embodiments provide methods of manufacturing a semiconductor device using the non-chemically amplified photoresist compositions.

According to example embodiments, there is provided a photoresist composition. The photoresist composition may include a polymer and a solvent. The polymer may include a first repeating unit and a second repeating unit, the first repeating unit having a diazoketo group, and the second repeating unit having a group containing silicon

In the example embodiments, the first repeating unit may be represented by following structural formulae (1)-(5).

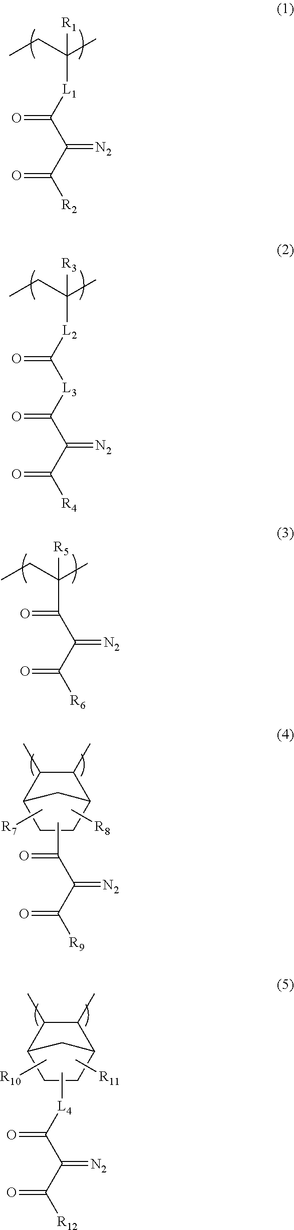

In structural formulae (1)-(5), R₁, R₃, R₅, R₇, R₈, R₁₀ and R₁₁ each independently may represent hydrogen, a substituted or unsubstituted C₁-C₄ alkyl group, a substituted or unsubstituted C₁-C₄ alkoxy group, or a substituted or unsubstituted C₁-C₄ phenyl group, R₂, R₄, R₆, R₉ and R₁₂ each independently may represent hydrogen, a substituted or unsubstituted C₁-C₃₀ alkyl group, a substituted or unsubstituted C₁-C₃₀ alkoxy group, a substituted or unsubstituted C₁-C₃₀ alkoxyalkyl group, a substituted or unsubstituted C₄-C₃₀ alicyclic hydrocarbon group, a substituted or unsubstituted C₆-C₃₀ aliphatic hydrocarbon group having a lactone structure, a substituted or unsubstituted C₆-C₃₀ aryl group, a substituted or unsubstituted C₆-C₃₀ heteroaryl group, or a substituted or unsubstituted C₆-C₃₀ aryloxy group, and L₁, L₂, L₃ and L₄ each independently may represent a divalent group selected from a substituted or unsubstituted C₁-C₃₀ alkylene group, a substituted or unsubstituted alkyleneoxy group, a substituted or unsubstituted C₁-C₃₀ oxyalkylene group, a substituted or unsubstituted C₁-C₃₀ carbonylalkylene group, a substituted or unsubstituted C₁-C₃₀ alkylenecarbonyl group, a substituted or unsubstituted C₁-C₃₀ carbonyloxyalkylene group, a substituted or unsubstituted C₁-C₃₀ carbonyloxyalkyleneoxy group, a substituted or unsubstituted C₆-C₃₀ arylene group, a substituted or unsubstituted C₆-C₃₀ aryleneoxy group, a substituted or unsubstituted C₆-C₃₀ oxyarylene group, a substituted or unsubstituted C₆-C₃₀ carbonylarylene group, a substituted or unsubstituted C₆-C₃₀ carbonyloxyarylene group, a substituted or unsubstituted C₆-C₃₀ arylenecarbonyloxy group, a substituted or unsubstituted C₆-C₃₀ oxy group, a substituted or unsubstituted C₆-C₃₀ oxycarbonyl group, a substituted or unsubstituted C₆-C₃₀ carbonyloxy group, or a substituted or unsubstituted C₁-C₃₀ aliphatic ester group, and combinations thereof.

In the example embodiments, the second repeating unit may be represented by following structural formulae (6)-(7).

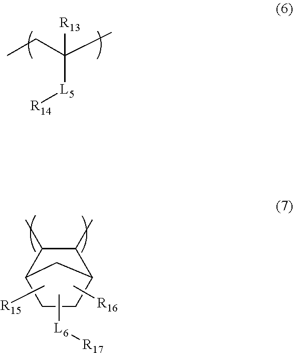

In structural formulae (6)-(7), R₁₃, R₁₅ and R₁₆ each independently may represent hydrogen, a substituted or unsubstituted C₁-C₄ alkyl group, a substituted or unsubstituted C₁-C₄ alkoxy group or a substituted or unsubstituted C₁-C₄ phenyl group, and R₁₄ and R₁₇ are groups having silicon and each independently may represent hydrogen, a substituted or unsubstituted C₁-C₃₀ alkyl group, a substituted or unsubstituted C₁-C₃₀ alkoxy group, a silyl group substituted with a C₆-C₃₀ aryl group, a siloxane residue group having a silicon(Si)-oxygen(O) bond or a silsesquioxane residue group having a silicon-oxygen bond. L₅ and L₆ each independently may represent a divalent group selected from a substituted or unsubstituted C₁-C₃₀ alkylene group, a substituted or unsubstituted C₁-C₃₀ alkyleneoxy group, a substituted or unsubstituted C₁-C₃₀ oxyalkylene group, a substituted or unsubstituted C₁-C₃₀ carbonylalkylene group, a substituted or unsubstituted C₁-C₃₀ alkylenecarbonyl group, a substituted or unsubstituted C₁-C₃₀ carbonyloxyalkylene group, a substituted or unsubstituted C₁-C₃₀ carbonyloxyalkyleneoxy group, a substituted or unsubstituted C₆-C₃₀ arylene group, a substituted or unsubstituted C₆-C₃₀ aryleneoxy group, a substituted or unsubstituted C₆-C₃₀ oxyarylene group, a substituted or unsubstituted C₆-C₃₀ carbonylarylene group, a substituted or unsubstituted C₆-C₃₀ carbonyloxyarylene group, a substituted or unsubstituted C₆-C₃₀ arylenecarbonyloxy group, a substituted or unsubstituted C₆-C₃₀ carbonyl group, a substituted or unsubstituted C₆-C₃₀ oxy group, a substituted or unsubstituted C₆-C₃₀ oxycarbonyl group, a substituted or unsubstituted C₆-C₃₀ carbonyloxy group, a substituted or unsubstituted C₁-C₃₀ aliphatic ester, and combinations thereof.

In the example embodiments, the polymer may further include a third repeating unit having a hydroxyl group.

In the example embodiments, the third repeating unit may be represented by following structural formulae (8)-(9).

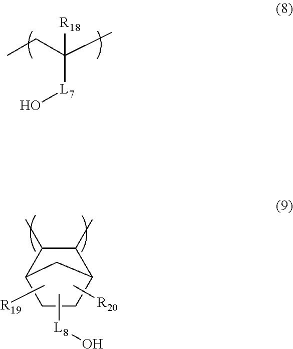

In structural formulae (8)-(9), R₁₈, R₁₉ and R₂₀ each independently represents hydrogen, a substituted or unsubstituted C₁-C₄ alkyl group, a substituted or unsubstituted C₁-C₄ alkoxy group or a substituted or unsubstituted C₁-C₄ phenyl group. L₇ and L₈ each independently represents a divalent group selected from a substituted or unsubstituted C₁-C₃₀ alkylene group, a substituted or unsubstituted C₁-C₃₀ oxyalkylene group, a substituted or unsubstituted C₁-C₃₀ carbonylalkylene group, a substituted or unsubstituted C₁-C₃₀ carbonyloxyalkylene group, a substituted or unsubstituted C₆-C₃₀ arylene group, a substituted or unsubstituted C₆-C₃₀ oxyarylene group, a substituted or unsubstituted C₆-C₃₀ carbonylarylene group, a substituted or unsubstituted C₆-C₃₀ carbonyloxyarylene group.

In the example embodiments, the polymer may include a first repeating unit represented by following structural formula (10) and a second repeating unit having polyhedral oligomer silsesquioxane (POSS) residue at a side chain of the second repeating unit.

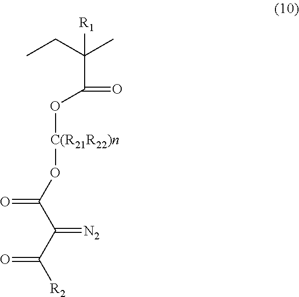

In structural formula (10), R₁ may represent hydrogen, a substituted or unsubstituted C₁-C₄ alkyl group, a substituted or unsubstituted alkoxy group or a substituted or unsubstituted C₁-C₄ phenyl group, and R₂ may represent a substituted or unsubstituted C₁-C₃₀ alkyl group, a substituted or unsubstituted C₁-C₃₀ alkoxy group, a substituted or unsubstituted C₁-C₃₀ alkoxyalkyl group, a substituted or unsubstituted C₄-C₃₀ alicyclic hydrocarbon group, a substituted or unsubstituted C₆-C₃₀ aliphatic hydrocarbon group containing a lactone structure, a substituted or unsubstituted C₆-C₃₀ aryl group, a substituted or unsubstituted C₆-C₃₀ heteroaryl group, or a substituted or unsubstituted C₆-C₃₀ aryloxy group. R₂₁ and R₂₂ each independently may represent hydrogen, a substituted or unsubstituted C₁-C₃₀ aliphatic hydrocarbon group, a substituted or unsubstituted C₄-C₃₀ alicyclic hydrocarbon group, or a substituted or unsubstituted C₆-C₃₀ aromatic hydrocarbon group. n may represent an integer between 1 and 30.

According to example embodiments, there is provided a method of forming a pattern. In the method, a photoresist film may be formed on a substrate by coating a photoresist composition including a polymer and a solvent. The polymer may include a first repeating unit and a second repeating unit, the first repeating unit having a diazoketo group, and the second repeating unit having a group containing silicon. The photoresist film may be partially exposed by using a light source. A photoresist pattern may be formed by developing the exposed photoresist film.

In the example embodiments, the first repeating unit may be represented by following structural formulae (1)-(5).

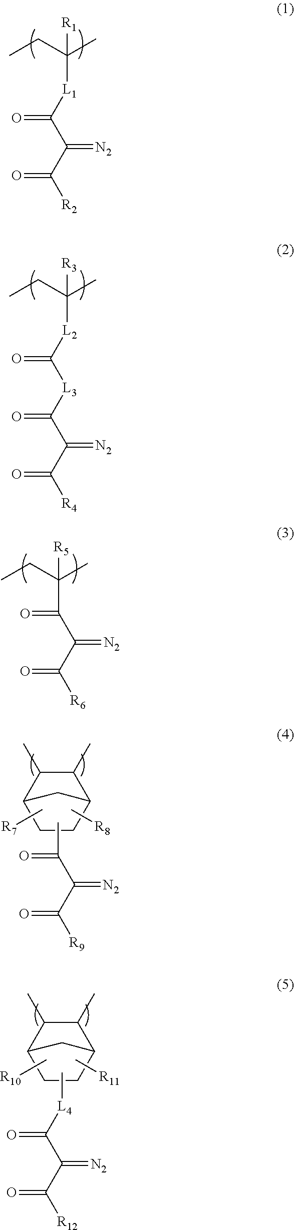

In structural formulae (1)-(5), R₁, R₃, R₅, R₇, R₈, R₁₀ and R₁₁ each independently may represent hydrogen, a substituted or unsubstituted C₁-C₄ alkyl group, a substituted or unsubstituted C₁-C₄ alkoxy group, or a substituted or unsubstituted C₁-C₄ phenyl group, R₂, R₄, R₆, R₉ and R₁₂ each independently may represent hydrogen, a substituted or unsubstituted C₁-C₃₀ alkyl group, a substituted or unsubstituted C₁-C₃₀ alkoxy group, a substituted or unsubstituted C₁-C₃₀ alkoxyalkyl group, a substituted or unsubstituted C₄-C₃₀ alicyclic hydrocarbon group, a substituted or unsubstituted C₆-C₃₀ aliphatic hydrocarbon group having a lactone structure, a substituted or unsubstituted C₆-C₃₀ aryl group, a substituted or unsubstituted C₆-C₃₀ heteroaryl group, or a substituted or unsubstituted C₆-C₃₀ aryloxy group, and L₁, L₂, L₃ and L₄ each independently may represent a divalent group selected from a substituted or unsubstituted C₁-C₃₀ alkylene group, a substituted or unsubstituted C₁-C₃₀ alkyleneoxy group, a substituted or unsubstituted C₁-C₃₀ oxyalkylene group, a substituted or unsubstituted C₁-C₃₀ carbonylalkylene group, a substituted or unsubstituted C₁-C₃₀ alkylenecarbonyl group, a substituted or unsubstituted C₁-C₃₀ carbonyloxyalkylene group, a substituted or unsubstituted C₁-C₃₀ carbonyloxyalkyleneoxy group, a substituted or unsubstituted C₆-C₃₀ arylene group, a substituted or unsubstituted C₆-C₃₀ aryleneoxy group, a substituted or unsubstituted C₆-C₃₀ oxyarylene group, a substituted or unsubstituted C₆-C₃₀ carbonylarylene group, a substituted or unsubstituted C₆-C₃₀ carbonyloxyarylene group, a substituted or unsubstituted C₆-C₃₀ arylenecarbonyloxy group, a substituted or unsubstituted C₆-C₃₀ oxy group, a substituted or unsubstituted C₆-C₃₀ oxycarbonyl group, a substituted or unsubstituted C₆-C₃₀ carbonyloxy group, or a substituted or unsubstituted C₁-C₃₀ aliphatic ester group, and combinations thereof.

In the example embodiments, the second repeating unit may have polyhedral oligomer silsesquioxane (POSS) residue at a side chain of the second repeating unit.

In the example embodiments, the photoresist composition may be devoid of a photo-acid generator.

In the example embodiments, partially exposing the photoresist film using the light source may include forming a ketene group at a position where N₂ previously existed by separating N₂ from the diazoketo group of the first repeating unit and forming a carboxylic acid by a reaction of the ketene group and residual moisture in the photoresist film.

In the example embodiments, the polymer may further include a third repeating unit having a hydroxyl group.

In the example embodiments, the third repeating unit may be represented by following structural formulae (8)-(9).

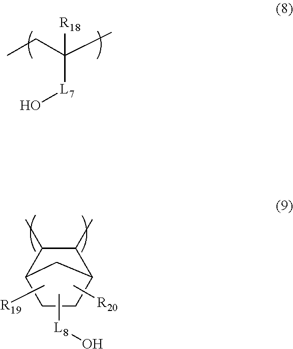

In structural formulae (8)-(9), R₁₈, R₁₉ and R₂₀ each independently may represent hydrogen, a substituted or unsubstituted C₁-C₄ alkyl group, a substituted or unsubstituted C₁-C₄ alkoxy group or a substituted or unsubstituted C₁-C₄ phenyl group. L₇ and L₈ each independently may represent a divalent group selected from a substituted or unsubstituted C₁-C₃₀ alkylene group, a substituted or unsubstituted C₁-C₃₀ oxyalkylene group, a substituted or unsubstituted C₁-C₃₀ carbonylalkylene group, a substituted or unsubstituted C₁-C₃₀ carbonyloxyalkylene group, a substituted or unsubstituted C₆-C₃₀ arylene group, a substituted or unsubstituted C₆-C₃₀ oxyarylene group, a substituted or unsubstituted C₆-C₃₀ carbonylarylene group, a substituted or unsubstituted C₆-C₃₀ carbonyloxyarylene group.

In the example embodiments, partially exposing the photoresist film by using the light source may include forming a ketene group at a position where N₂ previously existed by separating N₂ from the diazoketo group of the first repeating unit and forming a ester bond by a reaction of the ketene group and a hydroxyl group in the third repeating unit.

In the example embodiments, the photoresist film may be baked to remove residual moisture therefrom before partially exposing the photoresist film.

According to example embodiments, there is provided a method of forming a pattern. In the method, a lower resist film may be formed on a substrate. An upper resist film may be formed on the lower resist film by coating a photoresist composition including a first repeating unit and a second repeating unit, the first repeating unit having a diazoketo group, and the second repeating unit having a group containing silicon. The upper resist film may be partially exposed by using a light source. An upper resist pattern may be formed by developing the exposed upper resist film. A bi-layered resist pattern may be formed on the substrate by performing an etching process on the lower resist film using the upper resist pattern as an etching mask to form a lower resist pattern, the bi-layered resist pattern including the lower resist pattern and the upper resist pattern.

In the example embodiments, an etching object layer may be formed on the substrate and an etching object layer pattern may be formed by performing an etching process on the etching object layer using the bi-layered resist pattern as an etching mask to the etching object layer before forming the lower resist film.

In the example embodiments, a trench may be formed on the substrate by performing an etching process using the bi-layered resist pattern as an etching mask.

In the example embodiments, the upper resist film may be formed to have a minimum thickness within a range in which the lower resist film is sufficiently etched.

### BRIEF DESCRIPTION OF THE DRAWINGS

FIGS. 1 and 2 are cross-sectional views illustrating a method of forming a pattern in accordance with example embodiments;

FIGS. 3 and 4 are cross-sectional views illustrating a method of forming a pattern in accordance with other example embodiments;

FIGS. 5 to 7 are cross-sectional views illustrating a method of forming a bi-layered photoresist pattern in accordance with an example embodiment;

FIGS. 8 to 11 are cross-sectional views illustrating a method of manufacturing a Dynamic Random Access Memory (DRAM) device in accordance with example embodiments;

FIGS. 12 to 16 are cross-sectional views illustrating a method of manufacturing a flash memory device in accordance with example embodiments;

FIG. 17 is an electron microscope photograph of a photoresist pattern in embodiment 3;

FIG. 18 is an electron microscope photograph of a photoresist pattern in embodiment 4;

FIG. 19 is an electron microscope photograph of a bi-layered photoresist pattern in embodiment 5;

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, however do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In example embodiments, “alkyl” represents linear, branched or ring-shaped saturated hydrocarbon chains, and “alkylene” represents linear, branched or ring-shaped saturated divalent hydrocarbon chains. In an example embodiment, alkyl or alkylene may include 1 to 30 carbon atoms. Alternatively, alkyl or alkylene may include 1 to 10 carbon atoms. Alkyl and alkylene may be substituted with some substituent groups. Alternatively, alkyl and alkylene may be substituted with no substituent groups. Examples of alkyl may include a methyl group, an ethyl group, a propyl group, an isopropyl group, a butyl group, a t-butyl group, a cyclohexyl group, etc. An “aliphatic” functional group represents linear, branched or a ring-shaped saturated or unsaturated hydrocarbon chains without aromatic ring structure. Alternatively, “aryl” represents aromatic hydrocarbon chains. Aryl may include 3 to 30 carbon atoms and may have at least one ring. Example of aryl may include phenyl, naphthyl, anthracenyl, etc. Aryl may be substituted with some substituent groups. The aliphatic functional group may be substituted with some substituent groups. Alternatively, the aliphatic functional group may be substituted with no substituent groups. An alicyclic functional group represents ring-shaped aliphatic functional groups.

### First Photoresist Composition

In example embodiments, the first photoresist composition may include a polymer and a solvent. The polymer may have a first repeating unit containing a diazoketo group and a second repeating unit containing a group including silicon. The first photoresist composition may be a non-chemically amplified photoresist that includes no photoacid generator therein. In the first photoresist composition, the diazoketo group in the polymer may be decomposed by the stimulus of light, thereby causing a difference of solubility between an exposed portion and a non-exposed portion thereof even without the photoacid generator. Therefore, the conventional problems in the chemically amplified photoresist such as the increase of a line width roughness of a pattern and the nonuniform profile of the pattern may not occur. Additionally, the polymer may include silicon to have an improved etching resistance. The first photoresist composition may be used for an upper image layer of a bi-layered photoresist pattern because of the above characteristics.

The first repeating unit may include any repeating unit of a polymer having the diazoketo group at a side chain, and there is no limitation on the type of a basic chain structure or a substituent group. Poly(metha)acrylate, a vinyl polymer, an olefin polymer, a cyclicolefin polymer, polystyrene, a norbornene polymer, polyester, polyamide, polycarbonate, an unsaturated anhydride polymer, and the like may serve as the basic chain, however the basic chain may not be limited thereto. The basic chains may be used alone or in combinations thereof.

In the first repeating unit, the diazoketo group may be combined to the basic chain directly, or the diazoketo group may be combined to the basic chain via a divalent group of an aliphatic hydrocarbon or an aromatic hydrocarbon.

In example embodiments, the first repeating unit may be represented by following structural formulae (1)-(5).

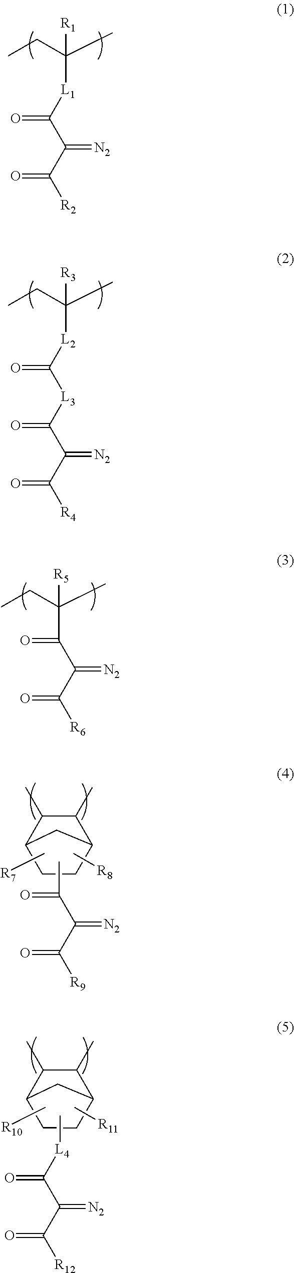

In structural formulae (1)-(5), R₁, R₃, R₅, R₇, R₈, R₁₀ and R₁₁ each independently may represent hydrogen, a substituted or unsubstituted C₁-C₄ alkyl group, a substituted or unsubstituted C₁-C₄ alkoxy group, or a substituted or unsubstituted C₁-C₄ phenyl group, R₂, R₄, R₆, R₉ and R₁₂ each independently may represent hydrogen, a substituted or unsubstituted C₁-C₃₀ alkyl group, a substituted or unsubstituted C₁-C₃₀ alkoxy group, a substituted or unsubstituted C₁-C₃₀ alkoxyalkyl group, a substituted or unsubstituted C₄-C₃₀ alicyclic hydrocarbon group, a substituted or unsubstituted C₆-C₃₀ aliphatic hydrocarbon group having a lactone structure, a substituted or unsubstituted C₆-C₃₀ aryl group, a substituted or unsubstituted C₆-C₃₀ heteroaryl group, or a substituted or unsubstituted C₆-C₃₀ aryloxy group, L₁, L₂, L₃ and L₄ each independently may represent a divalent group selected from a substituted or unsubstituted C₁-C₃₀ alkylene group, a substituted or unsubstituted C₁-C₃₀ alkyleneoxy group, a substituted or unsubstituted C₁-C₃₀ oxyalkylene group, a substituted or unsubstituted C₁-C₃₀ carbonylalkylene group, a substituted or unsubstituted C₁-C₃₀ alkylenecarbonyl group, a substituted or unsubstituted C₁-C₃₀ carbonyloxyalkylene group, a substituted or unsubstituted C₆-C₃₀ carbonyloxyalkyleneoxy group, a substituted or unsubstituted C₁-C₃₀ arylene group, a substituted or unsubstituted C₁-C₃₀ aryleneoxy group, a substituted or unsubstituted C₁-C₃₀ oxyarylene group, a substituted or unsubstituted C₁-C₃₀ carbonylarylene group, a substituted or unsubstituted C₁-C₃₀ carbonyloxyarylene group, a substituted or unsubstituted C₁-C₃₀ arylenecarbonyloxy group, a substituted or unsubstituted C₁-C₃₀ oxy group, a substituted or unsubstituted C₁-C₃₀ oxycarbonyl group, a substituted or unsubstituted C₁-C₃₀ carbonyloxy group, or a substituted or unsubstituted C₁-C₃₀ aliphatic ester group, and combinations thereof. In structural formulae (4) and (5), a group that may be combined to a norbonane ring may be combined to any positions where stable bonds are formed.

Examples of R₁, R₃, R₅, R₇, R₉, R₁₀ and R₁₁ may include hydrogen, a methyl group, an ethyl group, a propyl group, a butyl group, a phenyl group, a methoxy group, an ethoxy group, a propoxy group, a butoxy group, etc., and may not be limited thereto. Examples of R₂, R₄, R₆, R₉ and R₁₂ may include a methyl group, an ethyl group, a propyl group, a butyl group, a hexyl group, an octyl group, a decyl group, a dodecyl group, a hexadecyl group, a methoxy group, an ethoxy group, a propoxy group, a butoxy group, a phenyl group, a phenyloxy group, a cyclohexyl, etc., and may not be limited thereto. Examples of L₁, L₂, L₃ and L₄ may include a carbonyloxyethylene group, a carbonyloxypropylene group, a carbonyloxybutylene group, a carbonyloxyhexylene group, a carbonyloxydecylene group, a carbonyloxy group, an oxyethylene group, an oxypropylene group, an oxybutylene group, an oxyhexylene group, a carbonyloxyphenylene group, an ethylene group, a propylene group, a butylene group, a hexylene group, a decylene group, a dodecylene group, a hexadecylene group, etc., and may not be limited thereto.

In example embodiments, the first repeating unit may be represented by following structural formulae (10) and (11).

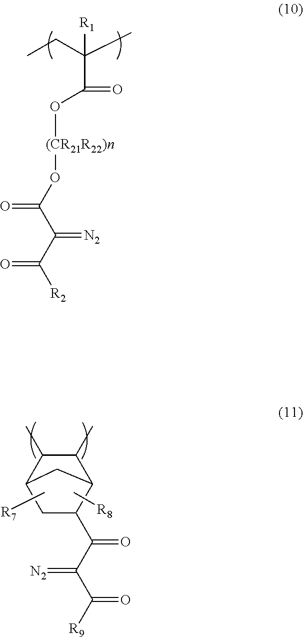

In structural formulae (10) and (11), examples of R₁, R₂, R₇, R₉ and R₉ may be the same as those of structural formulae (1) and (4). R₂₁ and R₂₂ each independently may represent hydrogen, a substituted or unsubstituted C₁-C₃₀ aliphatic hydrocarbon, a substituted or unsubstituted C₄-C₃₀ alicyclic hydrocarbon, or a substituted or unsubstituted C₆-C₃₀ aromatic hydrocarbon, and n may represent an integer between 1 and 30. Examples of R₂₁ and R₂₂ may include hydrogen, a methyl group, an ethyl group, a propyl group, a butyl group, a methoxy group, an ethoxy group, a propoxy group, a butoxy group, a phenyl group, a cyclohexyl group, etc., and may not be limited thereto.

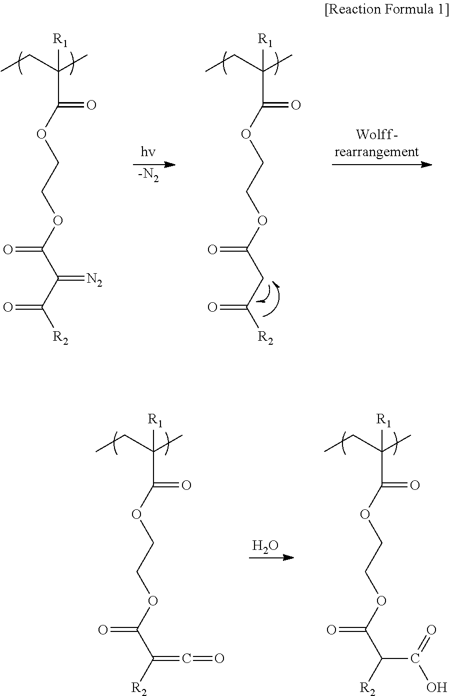

As illustrated in reaction formula (1), when the diazoketo group of the first repeating unit is stimulated by light, N₂ may be separated from the diazoketo group and a carbene may be formed at a position where N₂ previously existed. The carbene may be an unstable intermediate material, and may form a ketene group by Wolff rearrangement. The ketene group may be reacted easily with residual moisture in a photoresist film to form a carboxylic acid at an end of the first repeating unit. Through the chain reaction, the polymer in an exposed portion of the photoresist film may have the carboxylic acid, thereby being dissolved easily in an alkali developer. However, the polymer in a non-exposed portion of the photoresist film may have a relatively hydrophobic ending, thereby having a low solubility in the alkali developer. Therefore, the first photoresist composition including the polymer may be a positive-type photoresist.

The second repeating unit may include any repeating unit of a polymer having a group containing silicon improving the etching resistance of an organic photoresist, and a basic chain structure or a substituent group may not be limited thereto. Poly(metha)acrylate, a vinyl polymer, an olefin polymer, a cyclicolefin polymer, polystyrene, a norbornene polymer, polyester, polyamide, polycarbonate and an unsaturated anhydride polymer may serve as the basic chain, and the basic chain may not be limited thereto. The basic chains may be used alone or in combinations thereof. Examples of the group containing silicon may include a substituted or unsubstituted silyl group, a substituted or unsubstituted siloxane residue group, a substituted or unsubstituted silsesquioxane residue group, etc.

In example embodiments, the second repeating unit may be represented by following structural formulae (6) and (7).

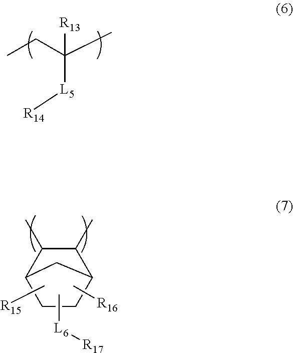

In structural formulae (6) and (7), R₁₃, R₁₅ and R₁₆ each independently may represent hydrogen, a substituted or unsubstituted C₁-C₄ alkyl group, a substituted or unsubstituted alkoxy group or a substituted or unsubstituted C₁-C₄ phenyl group, and R₁₄ and R₁₇ may be a group having silicon and each independently may represent hydrogen, a substituted or unsubstituted C₁-C₃₀ alkyl group, a substituted or unsubstituted C₁-C₃₀ alkoxy group, a silyl group substituted with a C₆-C₃₀ aryl group, a siloxane residue group having a silicon(Si)-oxygen(O) bond or a silsesquioxane residue group having a silicon-oxygen bond. L₅ and L₆ each independently may represent a divalent group selected from a substituted or unsubstituted C₁-C₃₀ alkylene group, a substituted or unsubstituted C₁-C₃₀ alkyleneoxy group, a substituted or unsubstituted C₁-C₃₀ oxyalkylene group, a substituted or unsubstituted C₁-C₃₀ carbonylalkylene group, a substituted or unsubstituted C₁-C₃₀ alkylenecarbonyl group, a substituted or unsubstituted C₁-C₃₀ carbonyloxyalkylene group, a substituted or unsubstituted C₁-C₃₀ carbonyloxyalkyleneoxy group, a substituted or unsubstituted C₆-C₃₀ arylene group, a substituted or unsubstituted C₆-C₃₀ aryleneoxy group, a substituted or unsubstituted C₆-C₃₀ oxyarylene group, a substituted or unsubstituted C₆-C₃₀ carbonylarylene group, a substituted or unsubstituted C₆-C₃₀ carbonyloxyarylene group, a substituted or unsubstituted C₆-C₃₀ arylenecarbonyloxy group, a substituted or unsubstituted C₆-C₃₀ carbonyl group, a substituted or unsubstituted C₆-C₃₀ oxy group, a substituted or unsubstituted C₆-C₃₀ oxycarbonyl group, a substituted or unsubstituted C₆-C₃₀ carbonyloxy group, a substituted or unsubstituted C₁-C₃₀ aliphatic ester, and combinations thereof.

Examples of R₁₃, R₁₅ and R₁₆ may include hydrogen, a methyl group, an ethyl group, a propyl group, a butyl group, a phenyl group, a methoxy group, an ethoxy group, a propoxy group, a butoxy group, etc., and may not be limited thereto. Examples of L₅ and L₆ may include a carbonyloxyethylene group, a carbonyloxydecylene group, a carbonyloxy group, an oxyethylene group, an oxypropylene group, an oxybutylene group, an oxyhexylene group, a carbonyloxyphenylene group, an oxyphenylene group, an ethylene group, a propylene group, a butylene group, a hexylene group, a decylene group, a dodecylene group, a hexadecylene group, etc., and may not be limited thereto.

Examples of R₁₄ and R₁₇ may include a silyl, group represented by —Si(R₂₃)x(OR₂₄)3-x. In the formula, x may represent an integer between 0 and 3, and R₂₃ and R₂₄ may represent a substituted or unsubstituted C₁-C₃₀ alkyl group, a substituted or unsubstituted C₆-C₃₀ aryl group, a substituted or unsubstituted C₄-C₃₀ cycloalkyl group. Examples of the silyl group represented by the formula may include a trimethoxysilyl group, a triethoxysilyl group, a tripropoxysilyl group, a tributoxysilyl group, a trimethylsilyl group, a triethylsilyl group, a tributylsilyl group, a methoxydimethylsilyl group, a ethoxydiethylsilyl group, a methoxydiethylsilyl group, a cyclohexyldimethylsilyl group, a cyclohexyldimethoxysilyl group, a phenyldimethylsilyl group, a phenyldimethoxysilyl group, etc., and may not be limited thereto.

Other examples of R₁₄ and R₁₇ may include a siloxane residue group having a Si—O bond or a silsesquioxane residue group having a Si—O bond. The siloxane group may refer to a group having a Si—O—Si—O backbone of which Si is combined to hydrogen or a hydrocarbon group. In the siloxane residue group serving as R₁₄ and R₁₇, one of Si of the siloxane group may be chemically combined to L₅ or L₆. Examples of the siloxane residue group may include a cyclotrisiloxane residue group, a pentamethylcyclotrisiloxane residue group, a cyclotetrasiloxane residue group, a heptamethylcyclotetrasiloxane residue group, a cyclopentasiloxane residue group, a nonamethylcyclopentasiloxane residue group, etc., and may not be limited thereto. A polyhedral oligomeric silsesquioxane (POSS) residue group represented by [R₂₅SiO1.5]y (R₂₅ may represent hydrogen or hydrocarbon group, and y=4, 6, 8, 10, 12, . . . ) may serve as the silsesquioxane residue group.

In example embodiments, the polymer may be a copolymer including a repeating unit not having the diazoketo group or the group containing silicon, in addition to the first repeating unit having the diazoketo group and the second repeating unit having the group containing silicon. Examples of a repeating unit, a monomer or a polymer forming the copolymer may include acrylate, methacrylate, an acrylic acid, a methacrylic acid, vinylester, vinylether, vinylalchol, vinylhalide, olefin, cyclicolefin, styrene, norbornene, polyester, polyamide, polycarbonate, anhydride maleate, an unsaturated anhydride, etc. These may be used alone or in combinations thereof.

In an example embodiment, the polymer may include a (metha)acrylate first repeating unit having the diazoketo group and a (metha)acrylate second repeating unit having the group containing silicon. In an example embodiment, the polymer may include a norbornene first repeating unit having the diazoketo group and a (metha)acrylate second repeating unit having the group containing silicon. In an example embodiment, the polymer may include a (metha)acrylate first repeating unit having the diazoketo group, a (metha)acrylate second repeating unit having the group containing silicon and a (metha)acrylate repeating unit having a lactone residue group. In an example embodiment, the polymer may include a norbornene first repeating unit having the diazoketo group, a (metha)acrylate second repeating unit having the group containing silicon and a (metha)acrylate repeating unit having a lactone residue group.

A molar proportion of the first repeating unit and the second repeating unit may be in a range of about 1:9 to about 9:1, however, may not be limited thereto. In an example embodiment, the molar proportion of the first repeating unit and the second repeating unit may be in a range of about 2:8 to about 8:2. In an example embodiment, the molar proportion of the first repeating unit and the second repeating unit may be in a range of about 5:5 to about 8:2. In an example embodiment, the molar proportion of the first repeating unit and the second repeating unit may be in a range of about 6:4 to about 8:2.

The polymer may be formed by copolymerizing a monomer having the diazoketo group and a monomer having the group containing silicon. For example, an unsaturated monomer having the diazoketo group and an unsaturated monomer having the group containing silicon may be dissolved in an organic solvent. An initiator such as azobisisobutyronitrile may be added to the solution, and the reactants may be stirred and reacted at a temperature range for a copolymerization, so that the copolymer may be formed by a radical polymerization.

In example embodiments, 2-(2-diazo-3-oxo-butyryloxy)ethyl methacrylate, 2-(2-diazo-3-oxo-butyryloxy)propyl methacrylate, 1-norbornenyl-2-diazo-1-oxo-3-methylpropanone, methyl 5-norbornenyl-2-diazo-3-oxopropyonate, etc. may serve as the monomer having the diazoketo group, and may not be limited thereto. Polyhedral oligomeric silsesquioxane-(1-propyl methacrylate)-hepta isobutyl, trimethylsilylpropyl methacrylate, triethoxysilylpropyl methacrylate, trimethylsilylpropyl norbornene, etc. may serve as the monomer having the group containing silicon, and may not be limited thereto. Benzoyl peroxide, 2,2-azobisisobutyronitrile, acetyl peroxide, lauryl peroxide, tert-butyl peracetate, di-tert-butyl peroxide, etc. may serve as the initiator, and may not be limited thereto. Cyclohexanone, cyclopentanone, tetrahydropyran, dimethylformamide, 1,4-dioxane, methylethylketone, benzene, toluene or combinations thereof may serve as the solvent, and may not be limited thereto.

The polymer may have a weight-average molecular weight in a range of about 3,000 g/mol to about 50,000 g/mol. In an example embodiment, the polymer may have a weight-average molecular weight in a range of about 3,000 g/mol to about 10,000 g/mol. The weight-average molecular weight of the polymer may be controlled depending on viscosity of the photoresist composition, a coatability of the photoresist composition, a pattern resolution, a pattern profile and/or a curing rate of the polymer.

The photoresist composition in accordance with example embodiments may include a solvent capable of dissolving the polymer. An organic solvent may mostly serve as the solvent, and non-limiting examples of the solvent may include alkylene glycol alkyl ether, alkylene glycol alkyl ester, alkylene glycol alkyl ether ester, ester, ether, lactone, ketone, an aliphatic or aromatic organic solvent, etc. Examples of the solvent may include diethylene glycol diethyl ether, diethylene glycol dimethyl ether, diethylene glycol monomethyl ether, diethylene glycol monoethyl ether, propylene glycol methyl ether, ethylene glycol monomethyl ether, ethylene glycol monoethyl ether, propylene glycol methyl ether, methyl 3-methoxypropionate, ethyl 3-ethoxypropionate, propylene glycol methyl ether acetate, cyclopentanone, cyclohexanone, 2-heptanone, 3-heptanone, 4-heptanone, γ-butyrolactone, ethyl lactate, methyl cellosolve acetate, ethyl cellosolve acetate, methyl ethyl ketone, tetrahydrofuran, xylene, etc. These may be used alone or in combinations thereof.

The solvent may be used in a range of about 30% to 1000% by weight based on a weight of the polymer. In an example embodiment, the solvent may be used in a range of about 50% to about 99.899% or about 70% to about 99.899% by weight based on a total weight of the photoresist composition. The content of the solvent may not be limited thereto, and may be controlled considering a viscosity of the photoresist composition, a coatibility of the photoresist composition and a curing rate of the polymer, etc. For example, the content of the solvent may be controlled so that the viscosity of the photoresist composition may be in a range of about 1 cP to about 30 cP at 25° C.

The photoresist composition in accordance with example embodiments may be formed by dissolving the polymer in the solvent. The photoresist composition may further include additives in addition to the polymer and the solvent to improve various properties. Examples of the additives may include a silane coupling agent, a dye, a surfactant, a filler, a viscosity modifier, etc., and may not be limited thereto. Examples of the filler may include barium sulfate, talc, a glass bubble, etc., and may not be limited thereto. Example of the viscosity modifier may include silica, and may not be limited thereto.

### Second Photoresist Composition

The second photoresist composition in accordance with example embodiments may include a polymer and a solvent. The polymer may have a first repeating unit containing a diazoketo group, a second repeating unit containing a group including silicon and a third repeating unit containing a hydroxyl group. Explanations of the first and second repeating units of the polymer and the solvent may be substantially the same as those of the first photoresist composition. Thus, repetitive explanations thereon are omitted here.

The third repeating unit may include any repeating unit of a polymer having the hydroxyl group, and there is no limitation on the type of a basic chain structure and a substituent group. Poly(metha)acrylate, a vinyl polymer, an olefin polymer, a cyclicolefin polymer, polystyrene, a norbornene polymer, polyester, polyamide, polycarbonate and an unsaturated anhydride polymer may serve as the basic chain, and the basic chain may not be limited thereto. The basic chains may be used alone or in combinations thereof.

In example embodiments, the third repeating unit may be represented by following structural formulae (8) and (9).

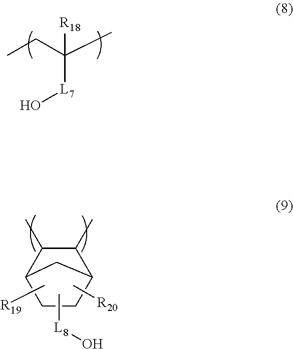

In structural formulae (8) and (9), R₁₈, R₁₉ and R₂₀ each independently may represent hydrogen, a substituted or unsubstituted C₁-C₄ alkyl group, a substituted or unsubstituted alkoxy group or a substituted or unsubstituted C₁-C₄ phenyl group. L₇ and L₈ each independently may represent a divalent group selected from a substituted or unsubstituted C₁-C₃₀ alkylene group, a substituted or unsubstituted C₁-C₃₀ oxyalkylene group, a substituted or unsubstituted C₁-C₃₀ carbonylalkylene group, a substituted or unsubstituted C₁-C₃₀ carbonyloxyalkylene group, a substituted or unsubstituted C₆-C₃₀ arylene group, a substituted or unsubstituted C₆-C₃₀ oxyarylene group, a substituted or unsubstituted C₆-C₃₀ carbonylarylene group, a substituted or unsubstituted C₆-C₃₀ carbonyloxyarylene group.

Examples of R₁₈, R₁₉ and R₂₀ may include hydrogen, a methyl group, an ethyl group, a propyl group, a butyl group, a phenyl group, a methoxy group, an ethoxy group, a propoxy group, a butoxy group, etc., and may not be limited thereto. Examples of L₇ and L₈ may include a carbonyloxyethylene group, a carbonyloxypropylene group, a carbonyloxybutylene group, a carbonyloxyhexylene group, a carbonyloxydecylene group, an oxyethylene group, an oxypropylene group, an oxybutylene group, an oxyhexylene group, a carbonyloxyphenylene group, an oxyphenylene group, an ethylene group, a propylene group, a butylene group, a hexylene group, a decylene group, a dodecylene group, a hexadecylene, etc., and may not be limited thereto.

Examples of a monomer having a hydroxyl group used for polymerizing a polymer may include hydroxyethyl methacrylate, hydroxypropyl methacrylate, hydroxyphenyl methacrylate, hydroxystyrene, vinyl alcohol, hydroxyethyl norbornene, hydroxypropyl norbornene, etc., and may not be limited thereto.

A molar proportion of the first repeating unit and the third repeating unit may be in a range of about 1:9 to about 9:1, and may not be limited thereto. A molar proportion of the second repeating unit and the third repeating unit may be in a range of about 1:9 to about 9:1, and may not be limited thereto.

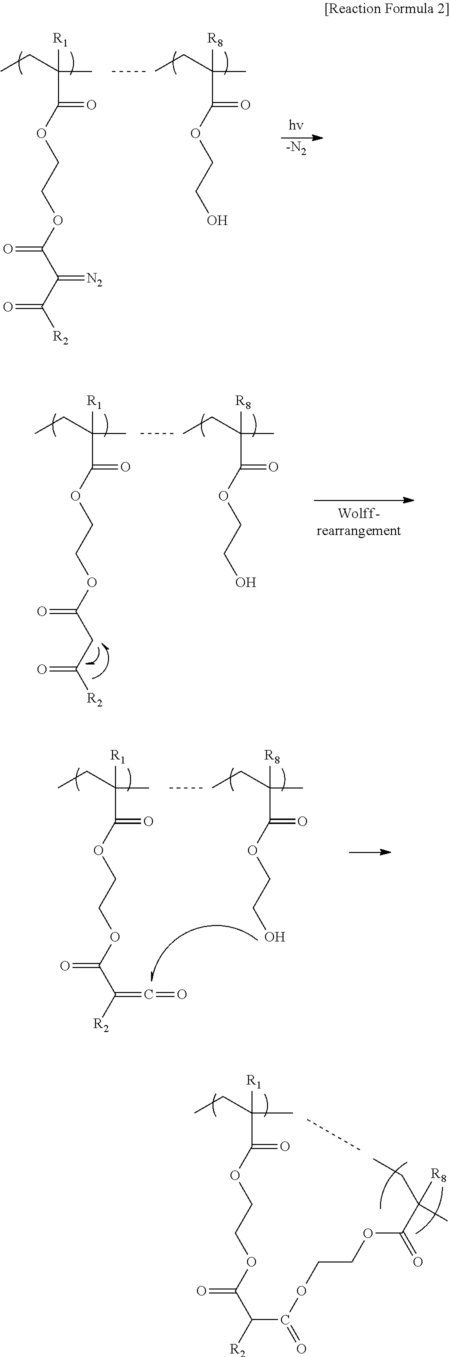

As illustrated in reaction formula (2), when the diazoketo group of the first repeating unit is stimulated by light, N₂ may be separated from the diazoketo group and a carbene may be formed at the position where N₂ previously existed. The carbene is an intermediate material, and may form a ketene group by Wolff rearrangement. The ketene group may be reacted with adjacent hydroxyl groups to form a bridged bond. The polymer in an exposed portion in a photoresist film may have the bridged bond carboxylic acid due to the chain reaction, thereby not being dissolved in an alkali developer. However, the polymer in a non-exposed portion in the photoresist film may not have the bridged bond, thereby being dissolved easily in the alkali developer. Therefore, the second photoresist composition including the polymer may be a negative-type photoresist. In case of the negative-type photoresist, a negative-type photoresist pattern may be formed by the chain reaction using the bridged bond, regardless of the existence of the moisture in the air or in the photoresist film. However, in case of the positive-type photoresist, a positive-type photoresist pattern may be formed in the condition of the existence of the moisture. Therefore, the negative-type photoresist may be used for a patterning process that may be performed in a vacuum using an EUV (Extreme Ultraviolet) light source.

The polymer may have a weight-average molecular weight in a range of about 3,000 g/mol to about 50,000 g/mol. In an example embodiment, the polymer may have a weight-average molecular weight in a range of about 3,000 g/mol to about 10,000 g/mol. The weight-average molecular weight of the polymer may be controlled depending on viscosity of the photoresist composition, a coatibility of the photoresist composition, a pattern resolution, a pattern profile and/or a curing rate of the polymer.

### Method of Forming a Pattern

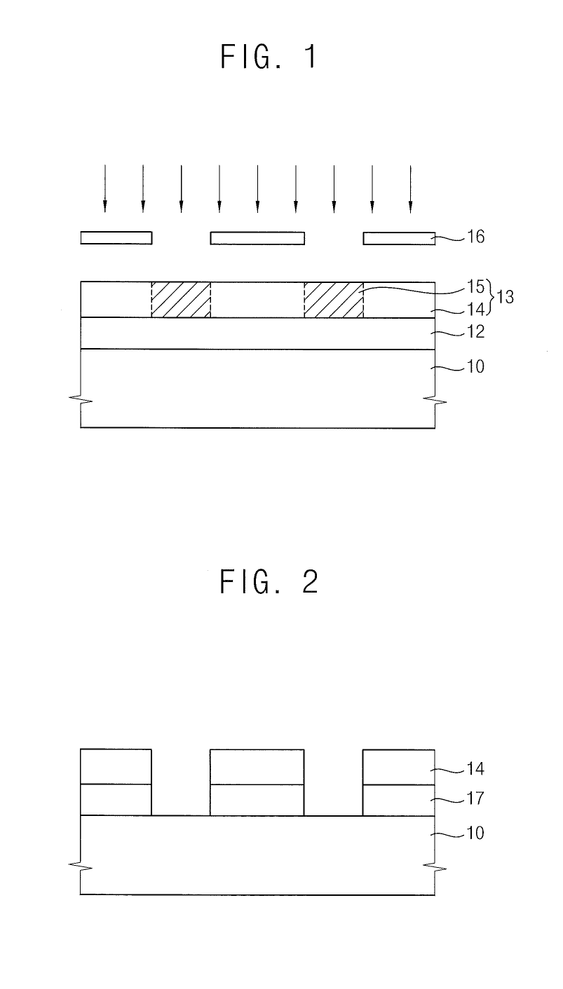

FIGS. 1 and 2 are cross-sectional views illustrating a method of forming a pattern in accordance with example embodiments.

Referring to FIG. 1, an etching object layer 12 may be formed on a substrate 10, and a photoresist film 13 may be formed on the etching object layer 12.

The substrate 10 may be an object on which the photoresist film 13 and the etching object layer 12 may be formed. Various types of substrates, e.g., a semiconductor substrate, a silicon-on-insulator (SOI) substrate, a glass substrate, a ceramic substrate, a printed circuit board (PCB), a polymer plate or a metal plate may serve as the substrate 10, and the substrate 10 may not be limited thereto. Additionally, various types of structures such as a device, a wiring, a pattern, a layer, a hole or a trench, etc. may be formed on the substrate 10 prior to forming the etching object layer 12.

The etching object layer 12 may be a layer on which images may be transferred from the photoresist film 13. There is no limitation on the types of the etching object layer 12, and examples of the etching object layer 12 may include a mask layer, a hard mask layer, an insulation layer, a conductive layer, an oxide layer, a nitride layer, an oxynitride layer, a metal layer, a metal nitride layer, a semiconductor layer or a polymer layer, etc. The etching object layer 12 may be formed by a layer deposition method such as a chemical vapor deposition (CVD) process, a physical vapor deposition (PVD) process or an atomic layer deposition (ALD) process, etc. or a layer coating method.

The photoresist film 13 may be formed on the etching object layer 12 using the first photoresist composition in accordance with example embodiments. The photoresist film 13 may be formed by coating the first photoresist composition having the first repeating unit containing the diazoketo group, the second repeating unit containing the group including silicon and the solvent. The photoresist film 13 may be formed by various layer coating methods known to those skilled in the art such as by a spin coating method, a spray coating method or a deep coating method, etc. The solvent may be removed by vaporization, and the vaporization may be promoted by heating.

Referring to FIG. 1 again, a light passing through a photomask 16 may be irradiated on a top surface of the photoresist film 13 so that an exposure process may be performed. The photoresist film 13 may be divided into a non-exposed portion 14 and an exposed portion 15 by the exposure process, so that an image of the photomask 16 may be transferred to the photoresist film 13. A light source used in the exposure process may include any light source capable of causing a decomposition reaction of the diazoketo group. For example, the light source may include various light sources such as EUV, ArF laser, KrF laser, electron beam, X-ray, Hg—Xe light, G-line ray of light, I-line ray of light, ultraviolet (UV) rays, deep-UV (DUV), radiation, etc.

As illustrated in reaction formula (1), in the exposed portion 15, when the diazoketo group of the first repeating unit is stimulated by light, N₂ may be separated from the diazoketo group and a carbene may be formed at the position where N₂ previously existed. The carbene is an intermediate material, and may form a ketene group by Wolff rearrangement. The photoresist film 13 may include a small amount of moisture, and the ketene group may be easily reacted with the residual moisture in the photoresist film 13 to form a carboxylic acid at an end of the first repeating unit. Through the chain reaction, the polymer in the exposed portion 15 may have the carboxylic acid, thereby being dissolved easily in an alkali developer. However, the polymer in the non-exposed portion 14 may have a relatively hydrophobic ending, thereby having a low solubility in the alkali developer. If the photoresist film 13 is not heated over 100° C. before the exposure process, the photoresist film 13 may have enough residual moisture to be reacted with the ketene group.

In a conventional chemically amplified photoresist, an acid generated from a photoacid generator in the exposed portion 15 may be diffused to the non-exposed portion 14, so that a line width roughness of a pattern may be increased and a gap between the patterns may become wider. However, the photoresist film 13 in accordance with example embodiments may be a non-chemically amplified photoresist with no photoacid generator therein, and the solubility of the diazoketo group in the polymer in the developer may be changed by the photo decomposition reaction, thereby reducing the line width roughness of a pattern and a nonuniform pattern profile.

Additionally, in the conventional chemically amplified photoresist, a process of PEB (post-exposure bake) may be performed in order to cause a chain chemical reaction of an acid. The acid may be diffused more actively through the process of PEB, thereby largely increasing a line width roughness. However, the photoresist film 13 in accordance with example embodiments may be a non-chemically amplified photoresist with no photoacid generator therein, and the solubility of the diazoketo group in the polymer in the developer may be changed by the photo decomposition reaction, thereby reducing the line width roughness of a pattern and a nonuniform pattern profile.

Referring to FIG. 2, the exposed portion 15 of the photoresist film 13 may be removed, and a photoresist pattern may be formed on the etching object layer 12 from the non-exposed portion 14. A solvent capable of removing a hydrophilic polymer may be used as the developer. For example, an akali developer such as hydroxy tetramethylammonium solution may be used. The photoresist pattern 14 may be formed to have a critical dimension of several nanometers to several hundred micrometers. In example embodiments, the photoresist pattern 14 may be formed to have a critical dimension of less than about several nanometers, e.g., 10 nm. In example embodiments, a composition having a viscosity of less than about 5 cP (25° C.)(for example, less than about 2 cP) may be thinly deposited using an ArF light source or an EUV light source, so that the photoresist pattern 14 may be formed to have a critical dimension of less than about 50 nm or even 30 nm.

An etching object layer pattern 17 may be formed on the substrate 10 by removing a portion of the etching object layer 12 exposed by the photoresist pattern 14. The etching object layer pattern 17 may be formed by a dry etching or a wet etching. In consideration of the etching rates of and the etching selectivity between the photoresist pattern 15 and the etching object layer 12, a proper etchant may be selected.

In FIGS. 1 and 2, the etching object layer 12 on the substrate 10 is patterned using the photoresist pattern 14 as an etching mask, however, the substrate 10 itself may be an etching object. In this case, a pattern image may be transferred to a top surface of the substrate 10, and a pattern, e.g., a trench or a hole may be formed at a portion of the substrate 10.

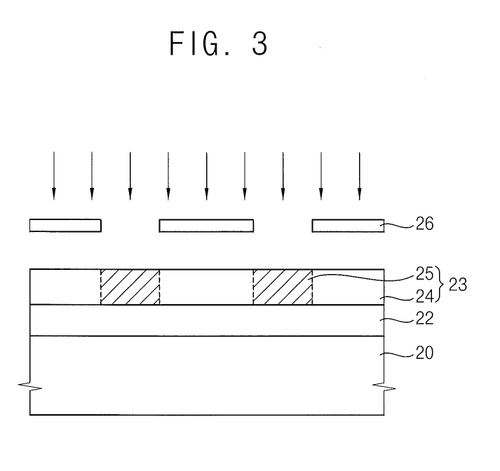

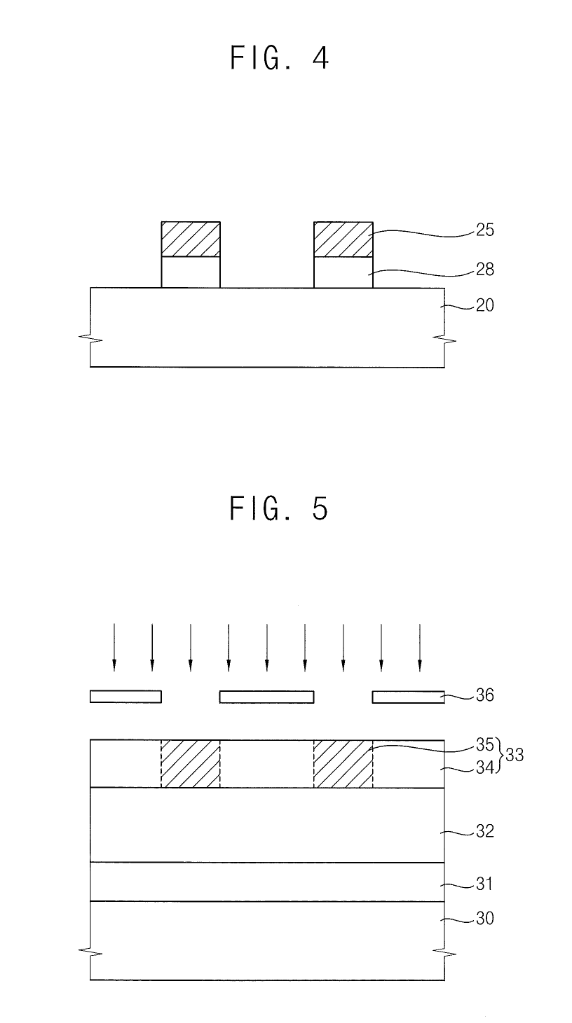

FIGS. 3 and 4 are cross-sectional views illustrating a method of forming a pattern in accordance with other example embodiments.

Referring to FIG. 3, a photoresist film 23 may be formed on an etching object layer 22 on a substrate 20 using the second photoresist composition including the polymer and the solvent. The polymer has the first repeating unit containing the diazoketo group, the second repeating unit containing the group including silicon, and the third repeating unit containing the hydroxyl group. The substrate 20 and the photoresist film 23 may be formed by processes substantially the same as those illustrated with reference to FIG. 1 except for the composition.

A light passing through a photomask 26 may be irradiated on a top surface of the photoresist film 23 so that an exposure process may be performed. The photoresist film 23 may be divided into a non-exposed portion 24 and an exposed portion 25 by the exposure process, so that an image of the photomask 26 may be transferred to the photoresist film 23. A light source used in the exposure process may be substantially the same as those illustrated with reference to FIG. 1.

In the exposed portion 25, as illustrated with reference to reaction formula (2), when the diazoketo group of the first repeating unit is stimulated by light, N₂ may be separated from the diazoketo group and a carbene may be formed at the position where N₂ previously existed. The carbene is an intermediate material, and may form a ketene group by Wolff rearrangement. The ketene group may form an ester bond by reaction with adjacent hydroxyl group. Through the chain reaction, bridged bonds may be formed between polymer chains, so that the polymer in the exposed portion 25 may not be dissolved in an organic developer. However, the polymer in the non-exposed portion 24 may not have the bridged bonds, thereby having a high solubility in the organic developer. The reaction between the ketene group and the hydroxyl group may compete against the reaction between the ketene group and the residual moisture. Therefore, in order to form a negative type pattern, an effect of the residual moisture may be decreased by baking the photoresist film 23 at a temperature sufficient to reduce the residual moisture before the exposure process. For example, the photoresist film 23 may be heated over about 100° C. before the exposure process, or the photoresist film 23 may be heated at a temperature of about 120° C. to about 130° C. If the moisture content is decreased by sufficiently refining the solvent, the baking process may be omitted.

Referring to FIG. 4, a developing process may be performed, so that the non-exposed portion 24 of the photoresist film 23 may be removed and a photoresist pattern may be formed on the etching object layer 22 from the exposed portion 25. The polymer of the exposed portion 25 may have bridged bonds, thereby not being dissolved in the organic developer to form the photoresist pattern. However, the polymer of the non-exposed portion 24 may be dissolved and removed easily in the organic developer. The developer may include any material capable of dissolving the polymer. For example, the developer may include an organic solvent such as ketone, acetate, ether, and alcohol. These may be used alone or in combinations thereof. Examples of the developer may include cyclohexanone, propylene glycol monomethyl ether acetate and diacetone alcohol, and the like.

A portion of the etching object layer 22 exposed by the photoresist pattern 25 may be removed to form an etching object layer pattern 28 on the substrate 20. The etching object layer pattern 28 may be formed by a dry etching or a wet etching. In consideration of the etching rates of and the etching selectivity between the photoresist pattern 25 and the etching object layer 22, a suitable etchant may be selected.

FIGS. 5 to 7 are cross-sectional views illustrating a method of forming a bi-layered photoresist pattern in accordance with example embodiments.

Referring to FIG. 5, an etching object layer 31, a lower resist film 32 and an upper resist film 33 may be formed sequentially on a substrate 30. The substrate 30 and the etching object layer 31 may be substantially the same as those illustrated with reference to FIG. 1. If the substrate 30 itself is used for an etching object, forming the etching object layer 31 may be omitted and a pattern, e.g., a trench or a hole may be formed on the substrate 30.

The lower resist film 32 and the upper resist film 33 may form a bi-layered photoresist film. The lower resist film 32 may be an organic film and be formed relatively thickly, thereby providing functions such as planarization, anti-reflection and/or etching resistance. The upper resist film 33 may be formed on the lower resist film 32 at a reduced thickness to provide imaging function.

The lower resist film 32 may be formed using an organic material such as an organic mask material, an organic photoresist material, or anti-reflection coating material. For example, the lower resist film 32 may be formed using an organic material including phenol resin, novolak resin, etc. The lower resist film 32 may be formed by performing a film spreading process such as spin coating, deep coating, spray coating, etc. When a bump exists on the etching object layer 31 or the substrate 30, the lower resist film 32 may be formed to have sufficient thickness to provide a flat upper surface.

The upper resist film 33 may be formed using the first photoresist composition in accordance with example embodiments. The upper resist film 33 may be formed to have a minimum thickness within a range in which the lower resist film 32 may be sufficiently etched. The first photoresist composition may include silicon, and thus the upper resist film 33 may be formed to have a good etching resistance even with a thin thickness. Therefore, the upper resist film 33 may have a low light absorption, and a high resolution pattern having a high aspect ratio may be formed using the upper resist film 33.

The upper resist film 33 may be formed by coating the composition including the polymer and the solvent. The polymer may have the first repeating unit containing the diazoketo group and the second repeating unit containing the group including silicon. The first photoresist composition may be applied by spin coating.

Referring to FIG. 5 again, a light passing through a photomask 36 may be irradiated on a top surface of the upper resist film 33 so that an exposure process may be performed. The upper resist film 33 may be divided into a non-exposed portion 34 and an exposed portion 35 by the exposure process, so that an image of the photomask 36 may be transferred to the upper resist film 33.

In the exposed portion 35, the diazoketo group may form a ketene group by being stimulated by light, and the ketene group may be reacted with the residual moisture, thereby forming a carboxylic acid at the side chain of the polymer. Therefore, a polymer in the exposed portion 35 may have the carboxylic acid at an end of the polymer, so that the polymer may be dissolved in an alkali developer.

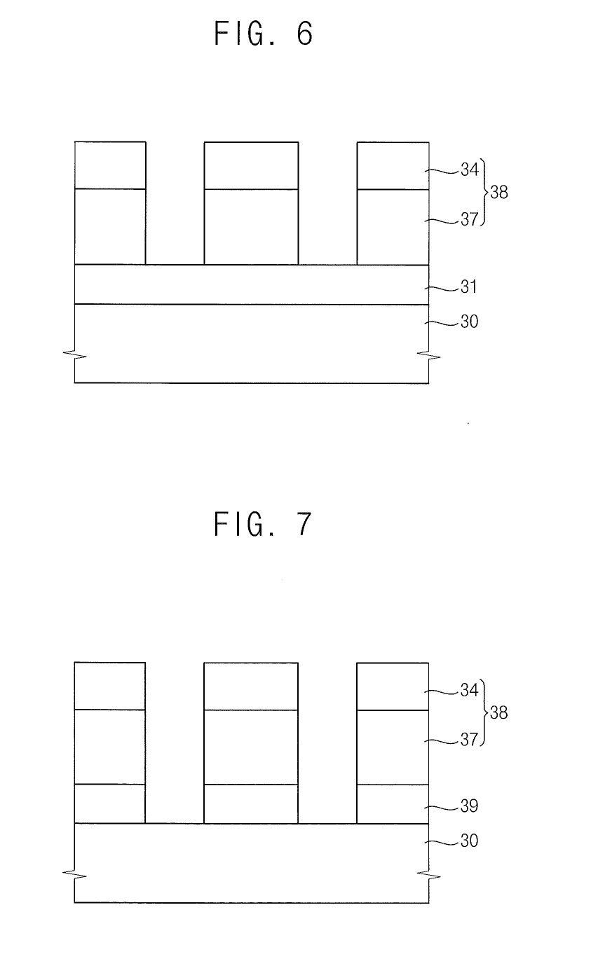

Referring to FIG. 6, the exposed portion 35 of the upper resist film 33 may be removed using the developer, and an upper resist pattern may be formed from the non-exposed portion 34.

The lower resist film 32 may be etched using the upper resist pattern 34 as an etching mask, so that a lower resist pattern 37 may be formed on the etching object layer 31. Therefore, a bi-layered resist pattern 38 including the upper resist pattern 34 and the lower resist pattern 37 may be formed on the etching object layer 31.

A portion of the lower resist film 32 exposed by the upper resist pattern 34 may be removed by a dry etching or a wet etching using an etchant having an etching selectivity there between. In example embodiments, the exposed portion of the lower resist film 32 may be removed by an etching process using oxygen plasma. The upper resist pattern 34 may include silicon, and thus the upper resist pattern 34 may have a good etching resistance to the oxygen plasma compared to the lower resist film 32.

Referring to FIG. 7, a portion of the etching object layer 31 exposed by the bi-layered resist pattern 38 may be removed by an etching process, so that an etching object layer pattern 39 may be formed on the substrate 30. The etching process may include the dry etching or the wet etching. When the substrate 30 is used for an etching object, forming the etching object layer 31 may be omitted.

In FIGS. 5 to 7, a positive type pattern is formed using the first photoresist composition. However, a negative type bi-layered resist pattern may be also formed using the second photoresist composition. In this case, in the exposed portion, the diazoketo group may form a ketene group by being stimulated by light, and the ketene group may be reacted with the hydroxyl group of adjacent polymer chain, thereby forming a bridged bond. Therefore, the exposed portion may not be dissolved in an organic developer. Therefore, the non-exposed portion may be removed during the developing process, so that a negative type imaging may be performed.

The above method may be used for forming an integrated circuit device, a memory device, a PCB, microelectromechanical systems (MEMS), a micromachine, a display device, an image display device, and a fine pattern of electronic devices, etc. For example, various types of patterns, e.g., a trench, a contact hole, a pad, a plug, a word line, a bit line or an insulation layer pattern may be formed.

### Method of Manufacturing a Semiconductor Device

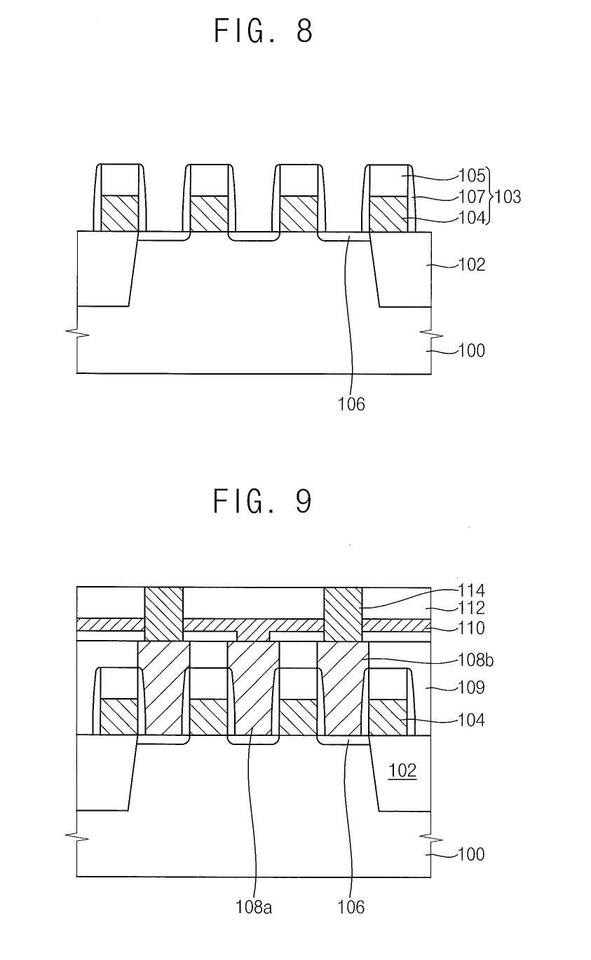

FIGS. 8 to 11 are cross-sectional views illustrating a method of manufacturing a Dynamic Random Access Memory (DRAM) device in accordance with example embodiments.

Referring to FIG. 8, an isolation layer 102 may be formed on a substrate 100 by a shallow trench isolation (STI) process. Particularly, a pad oxide layer (not shown), a mask layer (not shown) and a photoresist pattern (not shown) may be formed sequentially on the substrate 100, and the mask layer, the pad oxide layer and the substrate 100 may be etched sequentially to form a trench, and the trench may be filled with an insulation material, so that the isolation layer 102 may be formed.

The photoresist compositions and the methods of forming a pattern in accordance with example embodiments may be used in a photolithography process for forming the isolation layer 102. For example, a photoresist film (not shown) may be formed on the mask layer using the photoresist compositions in accordance with the example embodiments. By an exposure process and a developing process, the photoresist pattern may be formed on the mask layer. The photoresist pattern may have a good etching resistance, critical dimension roughness and pattern profile. The mask layer and the pad oxide layer may be etched sequentially using the photoresist pattern as an etching mask. After removing the photoresist pattern, a portion of the substrate 100 exposed by the mask layer may be etched.

A transistor including a source/drain 106 and a gate structure 103 may be formed on the substrate 100. The gate structure 103 may include a gate insulation layer (not shown), a gate electrode 104, a gate mask 107 and a gate spacer 107. A pattering process for forming the gate structure may be performed using the photoresist compositions and the methods of forming a pattern in accordance the example embodiments.

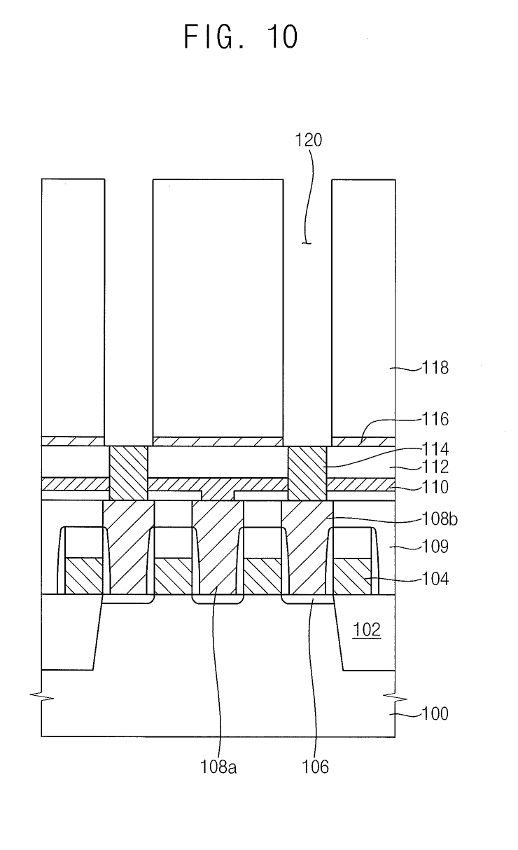

Referring to FIG. 9, a first insulating interlayer 109 covering the transistor may be formed on the substrate 100. The first insulating interlayer 109 may be partially etched to form contact holes (not shown), and the contact holes may be filled with a conductive material to form a first pad electrode 108a and a second pad electrode 108b. The first pad electrode 108a and the second pad electrode 108b may be connected to the source/drain 106. In an etching process for forming the contact holes, the photoresist compositions and the methods of forming a pattern in accordance with the example embodiments may be used.

A bit line 110 electrically connected to the first pad electrode 108a may be formed on the first insulating interlayer 109. The bit line 110 may be formed by forming a conductive layer on the first insulating interlayer 109 and patterning the conductive layer. A process for forming the bit line 110 may be performed using the photoresist compositions and the methods of forming a pattern in accordance with example embodiments.

A second insulating interlayer 112 may be formed on the first insulating interlayer 109 to cover the bit line 110. The second insulating interlayer 112 may be partially etched to form contact holes exposing the second pad electrode 108b. An etching process for forming the contact hole may be performed using the photoresist compositions and the methods of forming a pattern in accordance with example embodiments. The contact holes may be filled with a conductive material to form a contact plug 114.

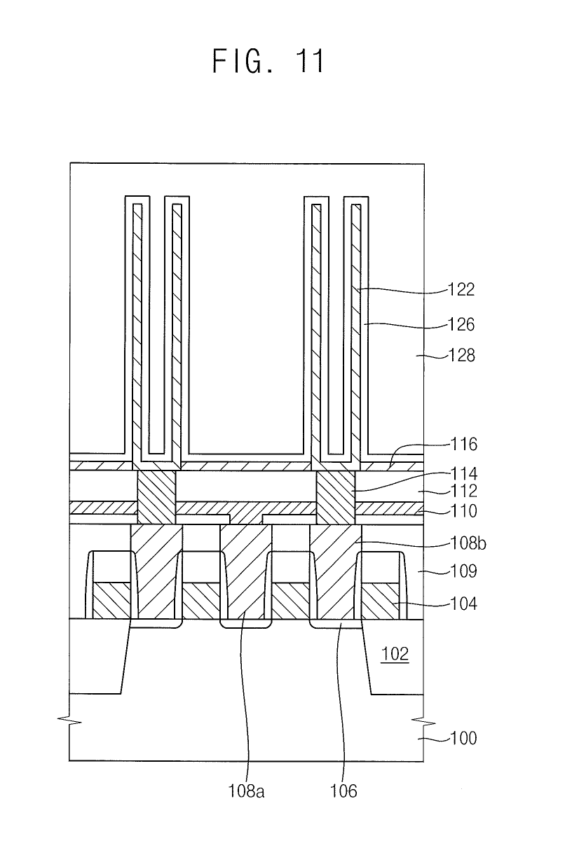

Referring to FIG. 10, an etch stop layer 116 may be formed on the second insulating interlayer 112 and the contact plug 114. A mold layer 118 may be formed on the etch stop layer 116. The etch stop layer 116 may be formed using a material having an etching selectivity with respect to the mold layer 118, e.g., silicon nitride. The mold layer 118 may be formed using an oxide such as TEOS, PSG, USG, BPSG, SOG or HDP-CVD oxide, etc., the selection of which is within the skill of one in the art.

The mold layer 118 and the etch stop layer 116 may be partially etched to form an opening 120 exposing a top surface of the contact plug 114. An etching process of the mold layer 118 may be performed using the photoresist compositions and the methods of forming a pattern in accordance with example embodiments.

Referring to FIG. 11, a conductive layer may be formed on an inner wall of the opening 120 and a top surface of the mold layer 118. The conductive layer may be formed using a conductive material such as a metal or a metal nitride. A buffer layer filling the opening 120 may be formed on the conductive layer. Upper portions of the buffer layer and the conductive layer may be planarized to form a lower electrode 122 on the inner wall of the opening 120. After forming the lower electrode 122, the mold layer 118 and the buffer layer may be removed to expose sidewalls of the lower electrode 122.

A dielectric layer 126 and an upper electrode 128 may be sequentially formed on the lower electrode 122 to form a capacitor. The dielectric layer 126 may be formed using a silicon oxide or an oxide having a high dielectric constant. The upper electrode 128 may be formed using a conductive material such as a metal or a metal nitride. A wiring (not shown) may be further formed to be electrically connected to the upper electrode 128, so that the DRAM device may be manufactured.

FIGS. 12 to 16 are cross-sectional views illustrating a method of manufacturing a flash memory device in accordance with example embodiments.

Referring to FIG. 12, dielectric layer patterns 212, 214 and 216 and a first conductive layer pattern 220 may be formed on a substrate 200. The substrate 200 may be divided into a cell region A and a core/peri regions B and C. The core/peri regions B and C may be divided into a low voltage transistor region B and a high voltage transistor region C.

After forming a dielectric layer and a first conductive layer on the substrate 200, the first conductive layer and the dielectric layer may be patterned by a photolithography process to form the first conductive layer pattern 220 and the dielectric layer patterns 212, 214 and 216. The dielectric layer may be formed by a thermal oxidation process. The dielectric layer may be formed relatively thinly on the cell region A and the low voltage transistor region B and relatively thickly on the high voltage transistor region C. The first conductive layer may be formed using a material such as polysilicon, a metal, etc.

The first conductive layer and the dielectric layer may be patterned using the photoresist compositions and the methods of forming a pattern in accordance with example embodiments. For example, a photoresist film (not shown) may be formed on the first conductive layer using the photoresist compositions, and a photoresist pattern may be formed on the first conductive layer by an exposure process and a developing process. The first conductive layer and the dielectric layer may be etched sequentially using the photoresist pattern as an etching mask, so that the first conductive layer pattern 220 and the dielectric layer patterns 212, 214 and 216 may be formed.

After forming the dielectric layer patterns 212, 214 and 216 and the first conductive layer pattern 220, a trench 201 may be formed by etching a portion of the substrate 200 exposed by the first conductive layer pattern 220 and the dielectric layer patterns 212, 214 and 216.

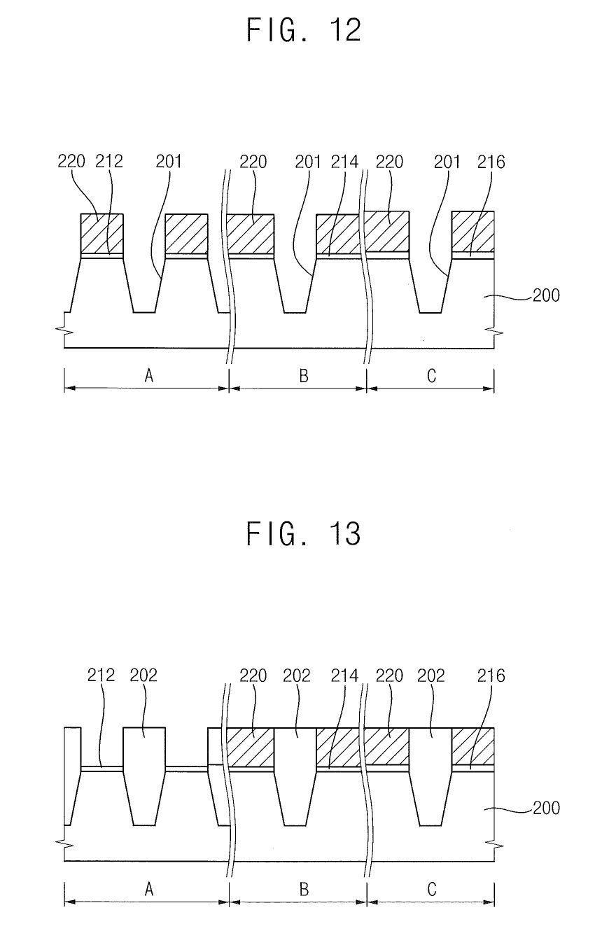

Referring to FIG. 13, the trench 201 may be filled with a conductive material to form an isolation layer 202. The isolation layer 202 may be formed by forming an insulation layer filling the trench 201 and performing a planarization process to expose a top surface of the first conductive layer pattern 220.

After forming the isolation layer 202, the first conductive layer pattern 220 on the cell region A may be removed. While removing the first conductive layer pattern 220, the core/peri regions B and C may be covered by a photosensitive mask. The photoresist compositions in accordance with example embodiments may be used as the photosensitive mask.

Referring to FIG. 14, a second conductive layer 222 may be formed on the first conductive layer pattern 220, the isolation layer 202 and the dielectric layer pattern 212. The second conductive layer 222 may be formed using a material substantially the same as or different from that of the first conductive layer 220. The second conductive layer 222 may not completely fill a space between the isolation layers 202 on the cell region A.

A sacrificial layer 230 may be formed on the second conductive layer 222. The sacrificial layer 230 may be formed to fill the remaining portion of the space between the isolation layers 202 on the cell region A.

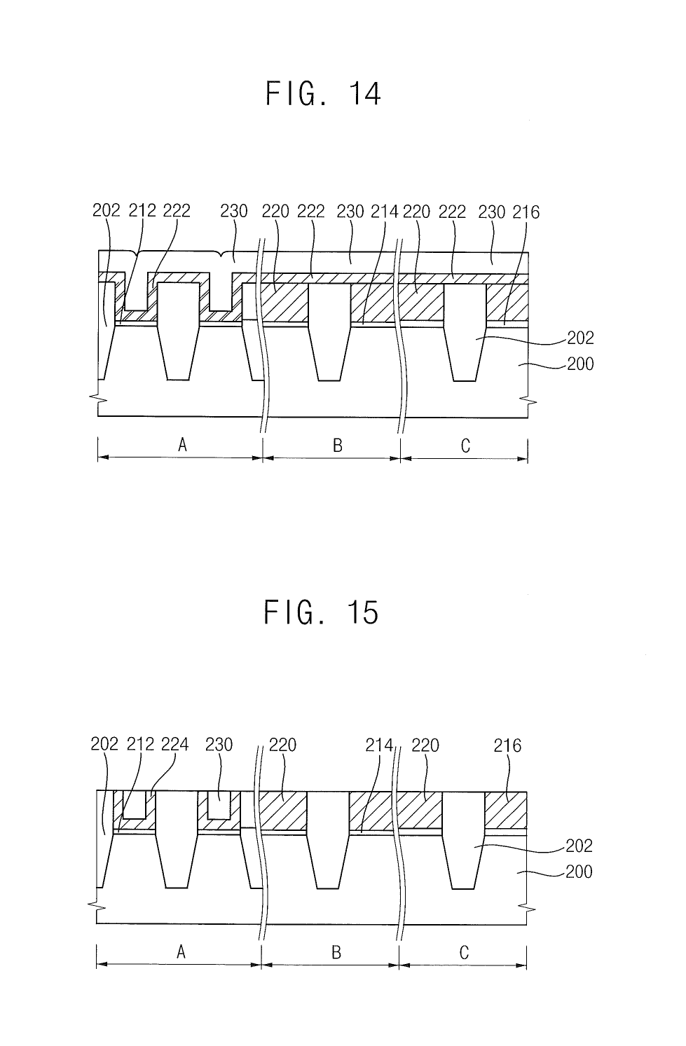

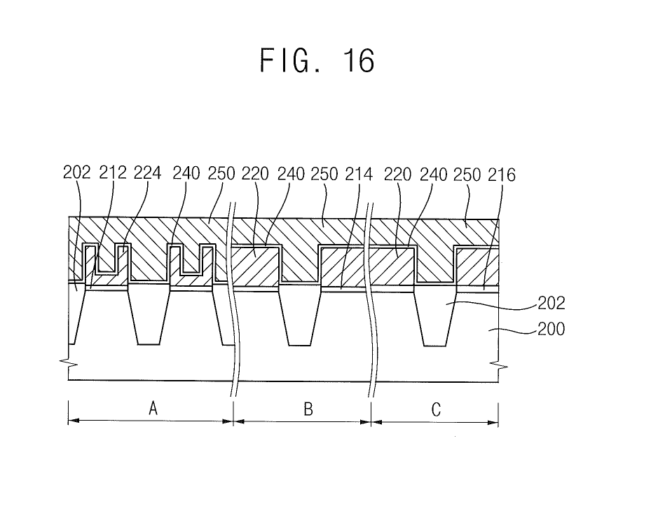

Referring to FIG. 15, a planarization process may be performed on the sacrificial layer 230 and the second conductive layer pattern 222 until top surfaces of the first conductive layer pattern 220 and the isolation layer 202 are exposed. Thus, a second conductive layer pattern 224 having a U shape may be formed on the dielectric layer pattern 212 on the cell region A, and a portion of the sacrificial layer 230 may remain on the second conductive layer pattern 224 on the cell region A.

Referring to FIG. 16, upper portions of the isolation layer 202 may be removed so that the second conductive layer pattern 224 on the cell region A and a sidewall of the first conductive layer pattern 220 on the core/peri regions B and C may be exposed. The portion of the sacrificial layer 230 remaining on the cell region A may be removed to expose a top surface of the second conductive layer pattern 224.

An insulating interlayer 240 may be formed on the first conductive layer pattern 220, the second conductive layer pattern 224 and the isolation layer 202. A control gate electrode layer 250 may be formed on the insulating interlayer 240. The control gate electrode layer 250, the insulating interlayer 240, the second conductive layer pattern 224 and the first conductive layer pattern 220 may be patterned in a direction perpendicular to a direction in which the isolation layer 202 extends. The photoresist compositions and the methods of forming a pattern in accordance with example embodiments may be used for the patterning process.

Until now, methods of manufacturing a DRAM device and a flash memory device using the photoresist compositions and the methods of forming a pattern in accordance with example embodiments have been illustrated, however, using the photoresist compositions and the methods, other types of memory devices such as a Ferroelectric Random Access Memory (FRAM) device, a Magnetic Random Access Memory (MRAM) device, a Phase-change Random Access Memory (PRAM) device, etc., a logic circuit device, an integrated circuit device, a thin film transistor, a display device, a PCB, a MEMS, a micromachine, an image sensor device, etc. may be also manufactured.

Hereinafter, some Examples are explained in detail, however, the present inventive concept may not be limited thereto.

### Synthesis Example 1

### Synthesis of a Monomer in which a Diazoketo Group is Introduced

A first reaction solution was formed by dissolving paratoluenesulfonyl azide (3.940 g, 0.02 mol) in anhydride acetonitrile (15 mL) under a nitrogen atmosphere. A second reaction solution was formed by dissolving 2-(methacryloiloxy)ethyl acetoacetate (4.416 g, 0.02 mol) and triethylamine (3.030 g, 0.03 mol) in anhydride acetonitrile. The first reaction solution was added to the second reaction solution slowly, and the mixed solution was reacted at a temperature of about 0° C. for about 20 minutes, and then the mixed solution was reacted at a temperature of about 30° C. for about 3 hours. After terminating the reaction by adding water into the mixed solution, an organic material was extracted using diethyl ether. After removing para sulfonamide by adding carbon tetrachloride into a solution including the organic material, a solvent of the solution was removed to obtain 2-(2-diazo-3-oxo-butyryloxy)ethyl methacrylate represented by following structural formula (12). A yield was about 89.5%. The structure of the monomer was identified by measuring ¹H NMR spectrum (CDCl3, 300 MHz). Peaks of δ6.09-6.08 (q, qH), 5.58-5.56 (m, 1H), 4.47-4.44 (m, 2H), 4.40-4.36 (m, 2H), 2.43 (s, 3H) and 1.91 (t, 3H) were detected.

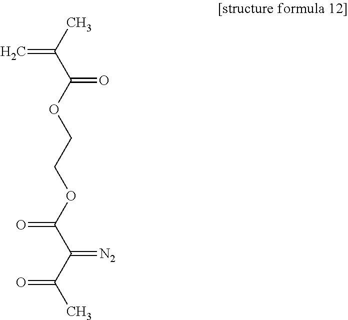

### Manufacturing a Polymer for Photoresist

### Example 1

### Manufacturing a Copolymer Including a Repeating Unit Having a Diazoketo Group And a Repeating Unit Having a Group Containing Silicon

After putting 2-(2-diazo-3-oxo-butyryloxy)ethyl methacrylate (0.72 g) manufactured in Synthesis Example 1, methacrylate substituted gamma butyrolactone (1.02 g) represented by following structural formula (13), polyhedral oligomeric silsesquioxane (POSS)-(1-propyl methacrylate)-heptais ° butyl substituent (0.934 g) and 2,2-azobisisobutyronitrile (0.03 g) into a flask, refined tetrahydrofuran (12 g) was added into the flask and dissolved. The mixture in the flask was radically polymerized under a nitrogen atmosphere at a temperature of about 65° C. for about 24 hours. After adding ethyl ether solution into the radically polymerized product, a solid product was obtained by using a filter. Poly[(2-(2-diazo-3-oxo-butyryloxy)ethyl methacrylate)-co-(gamma butyrolactone methacrylate)-co-(POSS-(1-propyl methacrylate)-heptaisobutyl)] was obtained by a vacuous drying. A yield of the polymer was about 45%, and a weight average molecular weight thereof was about 6,500 g/mol. It was confirmed that the polymer was decomposed at a temperature of about 170° C., and a glass transition temperature was not detected because of the low decomposition temperature.

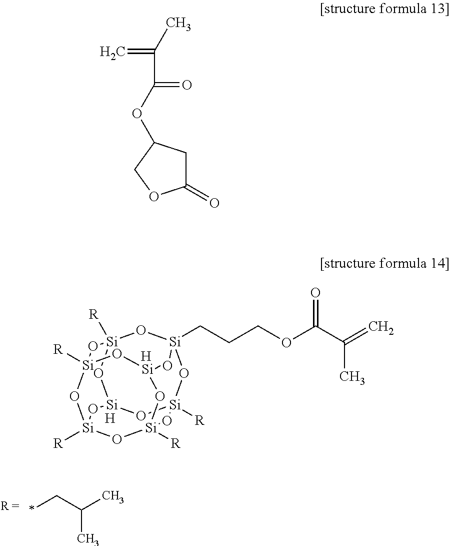

### Example 2

### Manufacturing a Copolymer Including a repeating Unit Having a Diazoketo Group, a Repeating Unit Having a Group Containing Silicon And a Repeating Unit Having a Group Containing Hydroxyl Group

After putting 2-(2-diazo-3-oxo-butyryloxy)ethyl methacrylate (0.72 g) manufactured in Synthesis Example 1, hydroxyethyl methacrylate (0.78 g), polyhedral silsesquioxane-(1-propyl methacrylate)-heptaisobutyl substituent (0.934 g) and 2,2-azobisisobutyronitrile (0.03 g) into a flask, refined tetrahydrofuran (12 g) was added into the flask. A mixture in the flask was radically polymerized under a nitrogen atmosphere at a temperature of about 65° C. for about 24 hours. After adding ethyl ether solution into the radically polymerized product, a solid product was obtained by using a filter. Poly[(2-(2-diazo-3-oxo-butyryloxy)ethyl methacrylate)-co-(hydrorxyethyl methacrylate)-co-(polyhedral silsesquioxane-(1-propyl methacrylate)-heptaisobutyl)] was obtained by a vacuous drying. A yield of the polymer was about 54%, and a weight average molecular weight was about 7,000 g/mol. It was confirmed that the polymer was decomposed at a temperature of about 170° C., and a glass transition temperature was not detected because of the low decomposition temperature.

### Example 3

### Manufacturing a Photoresist Composition And Forming a Positive Type Pattern

After dissolving 0.2 g of the polymer manufactured in Example 1 in 1.4 g of propyleneglycol monomethyl ether acetate in a lab from which ultraviolet rays were blocked, a photoresist composition was manufactured by filtering using a 0.2 μm filter. A viscosity of the photoresist composition was about 20 cP at a temperature of about 25° C.

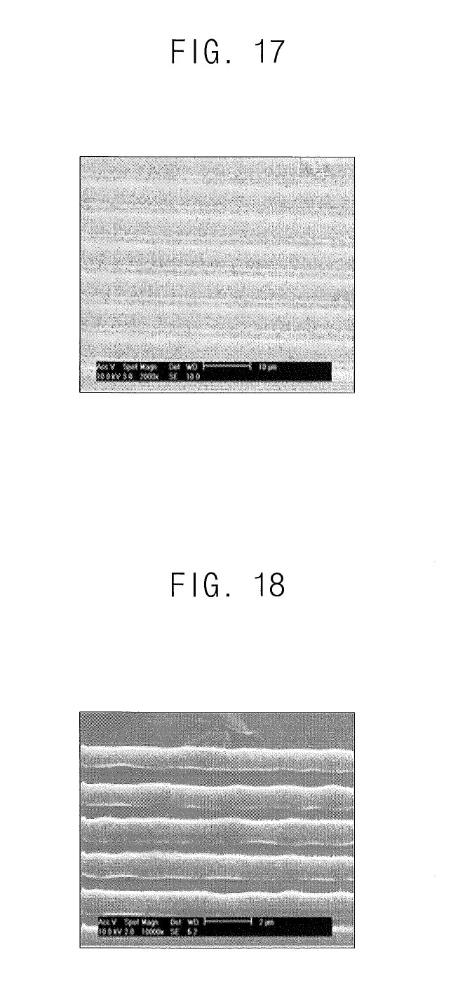

After spin-coating the photoresist composition on a silicon wafer, a photoresist film was manufactured by heating the photoresist composition at a temperature of about 100° C. for about 90 seconds. The photoresist film had a thickness of about 0.3 μm. The photoresist film was exposed at an irradiation amount of about 20 mJ by using an Hg/Xe lamp. A photoresist pattern having a critical dimension of about 5 μm was obtained by developing the exposed photoresist film for about 20 to about 30 seconds using 2.38% tetra methylammonium hydroxide solution as a developer without performing a post exposure baking process. An electron microscope photograph of the photoresist pattern is shown in FIG. 17. As shown in FIG. 17, a clear pattern having an improved profile was formed.

### Example 4

### Manufacturing a Photoresist Composition and Forming a Negative Type Pattern

After dissolving 0.2 g of the polymer manufactured in Example 2 in 1.4 g of propyleneglycol monomethyl ether acetate in a lab from which ultraviolet rays were blocked, a photoresist composition was manufactured by filtering using a 0.2 μm filter. A viscosity of the photoresist composition was about 20 cP at a temperature of about 25° C.

After spin-coating the photoresist composition on a silicon wafer, a photoresist film was manufactured by heating the photoresist composition at a temperature of about 100° C. for about 90 seconds. The photoresist film had a thickness of about 0.3 μm. The photoresist film was exposed at an irradiation amount of about 20 mJ by using an Hg/Xe lamp. A photoresist pattern having a critical dimension of about 5 μm was obtained by developing the exposed photoresist film for about 20 to about 30 seconds using tetrahydrofuran solution as a developer without performing a post exposure baking process. An electron microscope photograph of the photoresist pattern is shown in FIG. 18. As shown in FIG. 18, a clear pattern having an improved profile was formed. Unlike the positive type photoresist pattern depending on the concentration of residual moisture in air or the photoresist film, the negative type photoresist pattern was not sensitive to surroundings and had a relatively high sensitivity (20 mJ) to exposure. It means that the negative type photoresist pattern may be applied to an EUV light source under a high degree vacuum condition, and a bridged reaction may be performed effectively under the high degree vacuum condition.

### Example 5

### Forming a Bi-Layered Resist Pattern

Novolak resin was spin-coated on a silicon wafer in a lab from which ultraviolet rays were blocked. After exposing the novolak resin coating film for about 50 seconds, a lower planarized layer was obtained by heating the novolak resin coating film at a temperature of about 200° C. for about 10 minutes. After dissolving 0.1 g of the polymer obtained in Example 1 in 1.4 g of propyleneglycol monomethyl ether acetate, a photoresist composition was manufactured by filtering using a 0.2 μm filter.

After spin-coating the photoresist composition on a silicon wafer, a photoresist film was manufactured by heating the photoresist composition at a temperature of about 100° C. for about 90 seconds. The photoresist film had a thickness of about 0.15 μm. The photoresist film was exposed at an irradiation amount of about 20 mJ by using an Hg/Xe lamp. An upper imaging pattern including the photoresist was obtained by developing the exposed photoresist film for about 20 to about 30 seconds using 2.38% tetramethylammonium hydroxide solution as a developer without performing a post exposure baking process. An exposed portion of the lower novolak planarized layer was etched by an etching process using oxygen plasma for about 15 minutes in a plasma etching reactor. A dry etching process was performed at a flow rate of about 30 sccm, under a pressure of about 200 mTorr and with an RF power of about 100 W.

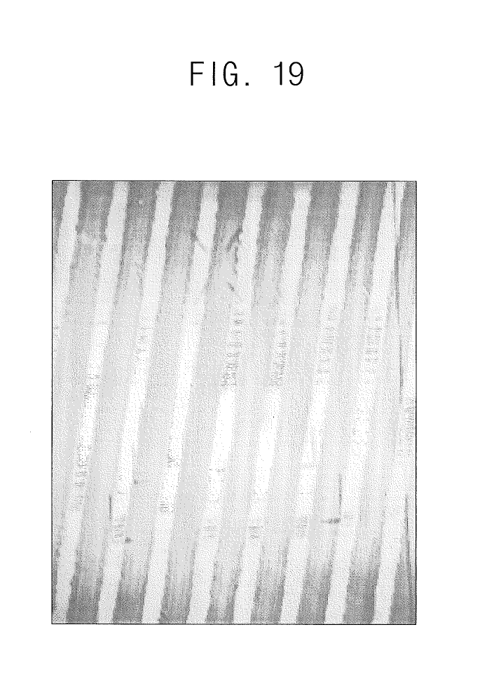

An electron microscope photograph of the photoresist pattern is shown in FIG. 19. As shown in FIG. 19, a clear bi-layered resist pattern was formed. By using the polymer including silicon, the photoresist composition may be used for not only a monolayer resist pattern but also an upper imaging layer of the bi-layered resist pattern. When the photoresist compositions in accordance with example embodiments are used for the upper imaging layer of the bi-layered resist pattern, the upper imaging layer may be formed relatively thinly, and thus the upper imaging layer may have a low light absorption and a high resolution pattern having a high aspect ratio may be formed using the upper imaging layer.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1.-6. (canceled)

7. A method of forming a pattern, the method comprising:
forming a photoresist film on a substrate by coating a photoresist composition including a polymer and a solvent, the polymer including a first repeating unit and a second repeating unit, the first repeating unit having a diazoketo group, and the second repeating unit having a group containing silicon;
partially exposing the photoresist film using a light source; and
forming a photoresist pattern by developing the exposed photoresist film.

8. The method of claim 7, wherein the first repeating unit is represented by following structural formulae (1)-(5). 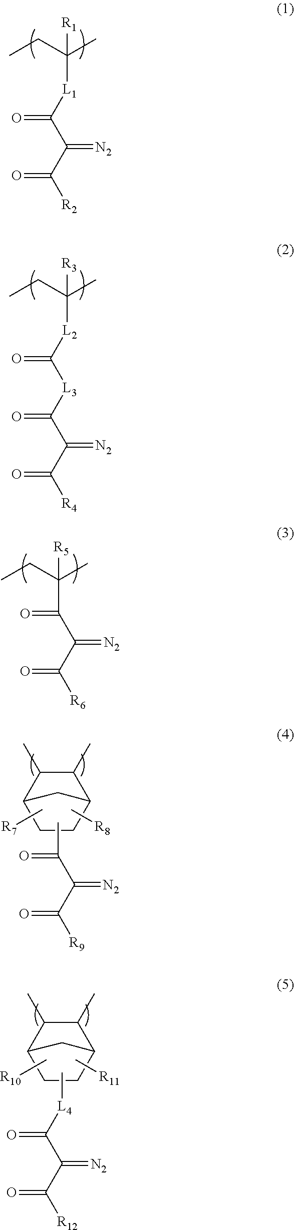
wherein R₁, R₃, R₅, R₇, R₈, R₁₀ and R₁₁ each independently represents hydrogen, a substituted or unsubstituted C₁-C₄ alkyl group, a substituted or unsubstituted C₁-C₄ alkoxy group, or a substituted or unsubstituted C₁-C₄ phenyl group,
R₂, R₄, R₆, R₉ and R₁₂ each independently represents hydrogen, a substituted or unsubstituted C₁-C₃₀ alkyl group, a substituted or unsubstituted C₁-C₃₀ alkoxy group, a substituted or unsubstituted C₁-C₃₀ alkoxyalkyl group, a substituted or unsubstituted C₄-C₃₀ alicyclic hydrocarbon group, a substituted or unsubstituted C₆-C₃₀ aliphatic hydrocarbon group having a lactone structure, a substituted or unsubstituted C₆-C₃₀ aryl group, a substituted or unsubstituted C₆-C₃₀ heteroaryl group, or a substituted or unsubstituted C₆-C₃₀ aryloxy group, and
L₁, L₂, L₃ and L₄ each independently represents a divalent group selected from a substituted or unsubstituted C₁-C₃₀ alkylene group, a substituted or unsubstituted C₁-C₃₀ alkyleneoxy group, a substituted or unsubstituted C₁-C₃₀ oxyalkylene group, a substituted or unsubstituted C₁-C₃₀ carbonylalkylene group, a substituted or unsubstituted C₁-C₃₀ alkylenecarbonyl group, a substituted or unsubstituted C₁-C₃₀ carbonyloxyalkylene group, a substituted or unsubstituted C₁-C₃₀ carbonyloxyalkyleneoxy group, a substituted or unsubstituted C₆-C₃₀ arylene group, a substituted or unsubstituted C₆-C₃₀ aryleneoxy group, a substituted or unsubstituted C₆-C₃₀ oxyarylene group, a substituted or unsubstituted. C₆-C₃₀ carbonylarylene group, a substituted or unsubstituted C₆-C₃₀ carbonyloxyarylene group, a substituted or unsubstituted C₆-C₃₀ arylenecarbonyloxy group, a substituted or unsubstituted C₆-C₃₀ oxy group, a substituted or unsubstituted C₆-C₃₀ oxycarbonyl group, a substituted or unsubstituted C₆-C₃₀ carbonyloxy group, or a substituted or unsubstituted C₁-C₃₀ aliphatic ester group, and combinations thereof.

9. The method of claim 8, wherein the second repeating unit has polyhedral oligomer silsesquioxane (POSS) residue at a side chain of the second repeating unit.

10. The method of claim 7, wherein the photoresist composition includes no photo-acid generator.

11. The method of claim 7, wherein partially exposing the photoresist film using the light source includes:
forming a ketene group at a position where N₂ previously existed by separating N₂ from the diazoketo group of the first repeating unit; and
forming a carboxylic acid by a reaction of the ketene group and residual moisture in the photoresist film.

12. The method of claim 7, wherein the polymer further includes a third repeating unit having a hydroxyl group.

13. The method of claim 12, wherein the third repeating unit is represented by following structural formulae (8)-(9), 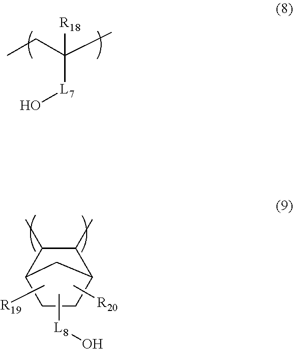
wherein, R₁₈, R₁₉ and R₂₀ each independently represents hydrogen, a substituted or unsubstituted C₁-C₄ alkyl group, a substituted or unsubstituted alkoxy group or a substituted or unsubstituted C₁-C₄ phenyl group, and
L₇ and L₈ each independently represents a divalent group selected from a substituted or unsubstituted C₁-C₃₀ alkylene group, a substituted or unsubstituted C₁-C₃₀ oxyalkylene group, a substituted or unsubstituted C₁-C₃₀ carbonylalkylene group, a substituted or unsubstituted C₁-C₃₀ carbonyloxyalkylene group, a substituted or unsubstituted C₆-C₃₀ arylene group, a substituted or unsubstituted C₆-C₃₀ oxyarylene group, a substituted or unsubstituted C₆-C₃₀ carbonylarylene group, a substituted or unsubstituted C₆-C₃₀ carbonyloxyarylene group.

14. The method of claim 12, wherein partially exposing the photoresist film using the light source includes:
forming a ketene group at a position where N₂ previously existed by separating N₂ from the diazoketo group of the first repeating unit; and
forming a ester bond by a reaction of the ketene group and a hydroxyl group in the third repeating unit.

15. The method of claim 12, prior to partially exposing the photoresist film, further comprising baking the photoresist film to remove residual moisture therefrom.

16. A method of forming a pattern, the method comprising:
forming a lower resist film on a substrate;
forming an upper resist film on the lower resist film by coating a photoresist composition including a first repeating unit and a second repeating unit, the first repeating unit having a diazoketo group, and the second repeating unit having a group containing silicon;
partially exposing the upper resist film using a light source;
forming an upper resist pattern by developing the exposed upper resist film; and
forming a bi-layered resist pattern on the substrate by performing an etching process on the lower resist film using the upper resist pattern as an etching mask to form a lower resist pattern, the bi-layered resist pattern including the lower resist pattern and the upper resist pattern.

17. The method of claim 16, prior to forming the lower resist film, further comprising:
forming an etching object layer on the substrate; and
forming an etching object layer pattern by performing an etching process on the etching object layer using the bi-layered resist pattern as an etching mask.

18. The method of claim 16, further comprising forming a trench on the substrate by an etching process using the bi-layered resist pattern as an etching mask.

19. The method of claim 16, wherein the upper resist film is formed to have a minimum thickness within a range in which the lower resist film is sufficiently etched.

20-21. (canceled)
